(19) United States
(12) Patent Application Publication
(10) Pub. No.: US 2010/0289997 A1
(43) Pub. Date: Nov. 18, 2010

(54) DISPLAY DEVICE

(75) Inventor: Seiji Suzuki, Kanagawa (JP)

Correspondence Address: YOUNG & THOMPSON, 209 Madison Street, Suite 500, Alexandria, VA, 22314, US

(73) Assignee: NEC CORPORATION, Tokyo (JP)

(21) Appl. No.: 12/812,558

(22) PCT Filed: Jan. 21, 2009
(86) PCT No.: PCT/JP2009/050856

§ 371 Date: Jul. 12, 2010

(30) Foreign Application Priority Data
Jan. 21, 2008 (JP) 2008-010927

(51) Int. Cl. G02F 1/1333; H01L 33/00

(52) U.S. Cl. 349/158; 257/59; 257/E33.053; 257/E33.055

(57) ABSTRACT

There is provided a contact hole including a lower layer metal disposed on an insulating substrate; an insulating film disposed on the lower layer metal film and having an opening; an interlayer connection layer formed by solidifying a conductive liquid material disposed extending to cover at least the lower layer metal film exposed by the opening and an insulating film edge portion at the opening; and an upper layer metal film disposed on the interlayer connection layer so that the upper layer metal film extends across a coverage boundary region of the interlayer connection layer to come in contact with the insulating film. The film thickness of the lower layer metal film exposed by the opening is thinner than the film thickness of the lower layer metal film not exposed by the opening.

### REFERENCE TO RELATED APPLICATION

This application is based upon and claims the benefit of the priority of Japanese patent application No. 2008-010927 (filed on Jan. 21, 2008), the disclosure of which is incorporated herein in its entirety by reference.

### TECHNICAL FIELD

The present invention relates to a display device. More specifically, the invention relates to an electrical connection structure between an upper layer metal film and a lower layer metal film with an insulating film having an opening sandwiched between the upper layer metal film and the lower layer metal film.

### BACKGROUND

In recent years, the trend of display devices has been increasingly toward a higher definition and a larger screen, due to market needs. In order to achieve the needs, it is necessary to reduce resistance of an interconnect such as a gate interconnect or a data interconnect connected to a thin-film transistor (Thin Film Transistor, hereinafter referred to as a “TFT”) which drives a display pixel, thereby overcoming the problem of insufficient writing to the TFT caused by a delay in the interconnect and so forth.

Currently, the above-mentioned problem is solved by use of aluminum (Al) or its alloy, such as an aluminum-neodium alloy (Al—Nd alloy). A display device that uses the Al—Nd alloy has been supplied to the market.

However, the Al—Nd alloy has a problem that an oxide film having a high resistance value is formed on a surface of the Al—Nd alloy during the fabrication process of the TFT.

For that reason, when the display device is formed by directly connecting the Al—Nd alloy to a film that forms a pixel electrode and is represented by a film of indium tin oxide (hereinafter referred to as ITO: Indium Tin Oxide), a connection resistance value demanded for the device cannot be satisfied.

As a measure against the problem about the connection resistance value, a cover film made of molybdenum (Mo), titaninum (Ti), chromium (Cr), or an alloy of molybdenum (Mo), titaninum (Ti), chromium (Cr) (which may also be referred to as high melting point metal film because generally, such the metals as described above have a higher melting point than an Al alloy-based metal such as the Al—Nd alloy) is disposed by being laminated on the surface of the Al—Nd alloy film. Then, the cover film is connected to an upper layer metal film for the pixel electrode or the like to form a contact hole.

This cover film is selected, in consideration of the excellence in acid resistance and base resistance, in addition to excellence in electrical connectivity. The cover film is selected, based on excellence in corrosion resistance against gas or a chemical used in the process of manufacture of the display device, for example. Then, after the completion of the display device, the cover film is selected, based on excellence in resistance against corrosion caused by moisture or gas in the air under a utilization environment.

The reason why acid resistance and base resistance are demanded for the cover film is as follows. Since the Al—Nd alloy is a metal mainly composed of Al, the Al—Nd alloy has an amphoteric metal property of being readily dissolved in acid or base solutions such as a cleaning solution, an etching solution, a developing solution, and a stripping solution used in the fabrication process of the display device. Further, in the utilization environment of the display device, the Al—Nd alloy is readily dissolved by the gas included in the air, such as sulfur gas or chlorine gas, in addition to the moisture in the air.

Further, the cover film is disposed and selected to achieve another object of preventing abnormal growth of crystal grains (hillock) of Al due to heating of the Al during the process. Al is a main component of the film of the Al—Nd alloy of a low melting point metal. Nd included in the Al—Nd alloy is added so as to prevent the Al hillock. However, the main component of the alloy is Al. Thus, it is not easy to completely prevent the Al hillock.

When the cover film is disposed for the contact hole, electrical connection with the pixel electrode can be established, corrosion resistance can be ensured, and the hillock can be prevented. Thus, there is an advantage that the display device can be readily manufactured. The cover film, however, has a drawback of having an interconnect resistance value higher than an Al alloy film such as the Al—Nd film.

The cover film serves to give connection to the pixel electrode or the like, chemical resistance, and the property of preventing the hillock. For that reason, the cover film may not be necessarily needed in terms of the configuration of the device if the above-mentioned problem can be solved.

Under such a background, in recent years, there has been proposed a new material system by which the cover film can be removed, which is advantageous in terms of production such as the cost of members, production yields, production TAT, and production tact, and which allows direct electrical connection to the ITO.

Further, when the display device is formed with such a metal, film thicknesses of the gate interconnect and the data interconnect can be reduced. As a result, there also arises an advantage that a coverage property by an insulating film located on an upper layer is easy to ensure.

The material system that does not need the cover film will be described below.

Patent Document 1 discloses a liquid crystal display device that uses an Al alloy by which direct, electrical connection to a pixel electrode can be made without arranging a cover film. Components of the AL alloy include gold (Au), zinc (Zn), copper (Cu), nickel (Ni), and so forth. Further, FIG. 2 of Patent Document 1 discloses a channel-protection TFT of an inverted staggered type, while FIG. 1 of Patent Document 1 discloses the liquid crystal display device formed of channel-protection TFTs of the inverted staggered type.

Patent Document 2 discloses a sputter target material capable of being directly and electrically connected to a transparent electrode without arranging a cover film, as in Patent Document 1. The target material is composed of an Al-based alloy including carbon (C) and at least one type of material from among Ni, cobalt (Co), and iron (Fe).

Likewise, Patent Document 3 discloses an element structure of a display device capable of being directly and electrically connected to a transparent electrode layer and/or a semiconductor layer without arranging a cover film. The disclosed alloy is composed of an aluminum-nickel (Al—Ni)-based alloy, and the element structure includes a test pattern in which the Al—Ni-based alloy is patterned, an insulating film is disposed on the Al—Ni-based alloy, an opening is provided in the insulating film, and a patterned ITO film is criss-crossed on the insulating film.

Patent Document 4 relates to a sputter target capable of being directly and electrically connected to a transparent electrode layer and/or a semiconductor layer without arranging a cover film. The sputter target disclosed in Patent Document 4 is an Al—Ni-rare-earth element alloy.

Non-patent Document 1 discloses a sputtering target which can be used for a TFT of a liquid crystal display device or the like, and can be directly and electrically connected to an ITO or an IZO (indium zinc oxide). The disclosed target is an Al—Ni—La alloy.

Non-patent Document 2 discloses Al alloy target ACX capable of being directly and electrically connected to the ITO.

Next, a description will be directed to a case where a liquid crystal device is manufactured by using a metal film (corresponding to each of Patent Documents 1 to 4, and Non-patent Documents 1 to 2) capable of being directly and electrically connected to a transparent electrode film without arranging the above-mentioned cover film in a known TFT substrate fabrication method, while using FIGS. 8A to 8D, 9A to 9D, and 10A to 10D.

Each of FIGS. 8A, 9A, and 10A shows a plane illustrating a display portion, a gate terminal portion, and a data terminal portion of a substrate with TFTs disposed thereon (hereinafter referred to as a TFT substrate). FIGS. 8B, 9B, and 10B respectively show sections of gate terminal portions taken along I-I′ lines of FIGS. 8A, 9A, and 10A, in schematic diagrams. FIGS. 8C, 9C, and 10C respectively show sections of pixel portions taken along II-II′ lines of FIGS. 8A, 9A, and 10A, in schematic diagrams. FIGS. 8D, 9D, and 10D respectively show sections of data terminal portions taken along III-III′ lines of FIGS. 8A, 9A, and 10A, in schematic diagrams. Referring to FIGS. 8A to 8D, 9A to 9D, and 10A to 10D, reference numeral 1 denotes a transparent substrate, reference numeral 2 denotes a first metal film, reference numeral 3 denotes a gate electrode, reference numeral 4 denotes a gate terminal, reference numeral 5 denotes a gate interconnect, reference numeral 6 denotes a first insulating film, reference numeral 8 denotes a contact film, reference numeral 9 denotes a second metal film, reference numeral 10 denotes a data interconnect, reference numeral 11 denotes a source electrode, reference numeral 12 denotes a drain electrode, reference numeral 13 denotes a data terminal, reference numeral 14 denotes a second insulating film, reference numeral 15 denotes a gate terminal hole, reference numeral 16 denotes a pixel connection hole, reference numeral 17 denotes a data terminal hole, reference numeral 20 denotes a pixel electrode, reference numeral 21 denotes a terminal protection pattern, and reference numeral 50 denotes an island pattern.

First, the alloy (hereinafter collectively referred to and described as the “Al—Ni-based alloy” in order to facilitate description) disclosed in each of Patent Documents 1 to 4 and Non-patent Documents 1 to 2 is deposited on the transparent substrate 1. The Al—Ni-based alloy is the first metal film 2. Then, using photolithography, a resist pattern is formed, and the first metal film 2 is etched to remove the resist, thereby patterning the gate electrode 3, gate terminal 4, and gate interconnect 5.

Assume herein that the Al—Nd film or the like which cannot be electrically connected to the transparent electrode without arranging the cover film is employed as the first metal film 2. In this case, after the cover film made of Ti, Mo, or the like has been formed on the metal, photolithography, etching, and removal are carried out, for patterning. In this known example, direct electrical connection can be made between the first metal film 2 and the transparent electrode. Thus, no cover film is disposed.

Secondly, the first insulating film 6 constituted from a silicon nitride film (SiNx), a semiconductor film 7 (a-Si) constituted from an amorphous silicon film, and the contact film 8 (n+-a-Si) in which phosphorous has been doped are deposited on an entire surface of the substrate to cover the pattern formed by the first metal film 2. Then, using photolithography, a resist pattern is formed, the contact film 8 and the semiconductor film 7 are etched to remove the resist, thereby forming the pattern in the shape of an island (hereinafter referred to as the island pattern 50). This island pattern 50 is formed over the gate electrode 3 with the first insulating film 6 sandwiched therebetween.

Thirdly, the Al—Ni-based alloy disclosed in each of Patent Documents 1 to 4 and Non-patent Documents 1 and 2, which is the second metal film 9, is formed over an entire surface of the substrate. Then, using photolithography, a resist pattern is formed, the second metal film 9 is etched to remove the resist, thereby patterning the data interconnect 10, source electrode 11, drain electrode 12, and data terminal 13.

In case the Al—Nd film or the like that cannot be electrically connected to the transparent electrode without arranging the cover film is employed as the second metal film 9, after the cover film made of Ti, Mo, or the like has been formed on the metal, photolithography, etching, and resist removal are carried out, for patterning. In this known example, direct electrical connection can be made between the second metal film 9 and the transparent electrode. Thus, no cover film is disposed.

Fourthly, before the resist pattern for the second metal film 9 is removed or after the resist pattern has been removed, the contact film 8 that is not covered with the data interconnect 10 and the source electrode 11 is removed to expose the semiconductor film 7. A channel is thereby formed. A portion of the semiconductor film may be removed, as necessary.

Then, in case the channel is formed without removing the resist, the resist is removed (refer to FIG. 8 for the above description).

Fifthly, the second insulating film 14 composed of a silicon nitride film is formed so that the members exposed on the substrate, such as the pattern formed by the second metal film 9, the island pattern with the semiconductor film 7 exposed therefrom, and the first insulating film 6, are covered. Then, using photolithography, a resist pattern is formed, the second insulating film 14 is etched to remove the resist, and the gate terminal hole 15, pixel connection hole 16, and data terminal hole 17 are patterned to provide openings (as shown in FIG. 9).

Sixthly, a transparent conductive film made of ITO is deposited over the substrate to cover the second insulating film 14, gate terminal hole 15, pixel connection hole 16, and data terminal hole 17. Then, using photolithography, a resist pattern is formed, and the transparent conductive film 14 is etched to remove the resist, the terminal protection pattern 21 is formed to cover the gate terminal hole 15 and the data terminal hole 17, and the pixel electrode 20 is formed to cover the pixel connection hole 16. The TFT substrate is thereby completed (as shown in FIG. 10).

Next, Patent Document 5 will be described using FIG. 12. FIG. 12A is a plan view, and FIG. 12B is a diagram showing a section taken along an A-A′ line of FIG. 12A. Referring to FIGS. 12A and 12B, reference numeral 201 denotes an insulating film, reference numeral 202 denotes an upper layer conductive film, reference numeral 203 denotes a lower layer conductive film, reference numeral 204 denotes a connection hole, reference numeral 205 denotes an inside region, reference numeral 206 denotes an outside region, reference numeral 207 denotes a conducting portion (intervening conducting portion), reference numeral 208 denotes an interlayer connection material, and reference numeral 209 denotes an interlayer connection material droplet position.

This known example is related to a connection method between the upper layer conductive film 202 and the lower layer conductive film 203 with the insulating film 201 sandwiched therebetween, and can be applied to a liquid crystal display device.

The upper layer conductive film 202 is a pixel electrode made of ITO, the lower layer conductive film 203 is a drain electrode made of Ti, the insulating film 201 is a silicon nitride film, and the interlayer connection material 208 connects the drain electrode and the pixel electrode.

This known example includes over a substrate the lower conductive film 203, insulating film 201, and upper layer conductive film 202 in this stated order. The upper layer conductive film 202 is of a structure in which the inside region 205 and the outside region 206 separated by the connection holes 24 are connected via at least one conducting portion (intervening conducting portion 207). In this structure, a conductive liquid material (hereinafter referred to as the interlayer connection material 208) is dropped onto a desired position (interlayer connection material droplet position 209) on the upper layer conductive film 202 using a method such as inkjet. The liquid material is flown to cover inclined portions of the connection holes 204 and the lower layer conductive film 203, thereby ensuring electrical connection between the upper layer conductive layer 202 and the lower layer conductive film 203.

In order to reduce the number of photomasks for use and improve productivity at a time of TFT substrate manufacture, an object of Patent Document 5 is to connect the upper layer conductive film 202 and the lower layer conductive film 203 with the insulating film 201 sandwiched therebetween by applying an interlayer insulating interconnect by inkjet to eliminate a variation in liquid droplet deposition without increasing the number of steps such as patterning (refer to paragraphs 0003 and 0008).

Patent Document 6 discloses a fabrication method including a step of forming an insulating film on a semiconductor substrate, a step of forming an opening in the insulting film, a step of wholly attaching a solution including a conductive material to an entire surface of the inside of the opening including small horizontal grooves generated at the bottom of the opening, a step of drying the solution including the conductive material wholly attached to the inside of the opening, thereby forming a conductive film, and a step of forming a barrier metal on the conductive film. Patent document 7 discloses a multilayer interconnect forming method in which a first conductive layer and a second conductive layer are laminated through an insulating layer, and the first conductive layer and the second conductive layer are connected via a through hole formed in the insulating layer. The method includes a step of forming a first conductive layer on a substrate, a step of forming in a through hole forming region on the first conductive layer a mask having a shape that is widened from the first conductive layer to an upper layer, a step of forming the insulating layer on the first conductive layer excluding the formed mask, a step of removing the mask to form a through hole in the insulating layer, and a step of forming a conductive member within the through hole and forming the second conductive layer in a form of being connected to the conductive member.

### Patent Document 1:

JP Patent Kokai Publication No. JP2004-214606A

### Patent Document 2:

JP Patent Kokai Publication No. JP2005-54273A

### Patent Document 3:

JP Patent Kohyo Publication No. JP2006-330662A

### Patent Document 4:

JP Patent Kokai Publication No. JP2006-225687A

### Patent Document 5:

JP Patent Kokai Publication No. JP2007-47602A

### Patent Document 6:

JP Patent Kokai Publication No. JP-H05-343536A

### Patent Document 7:

JP Patent Kokai Publication No. JP2005-32759A

### Non-patent Document 1:

The Semiconductor Industry News (2006. 8. 30. 10th page)

### Non-patent Document 2:

Homepage of Mitsui Mining & Smelting Co., Ltd.→Electronics Materials Business→PDV Materials Division→Developed-New Product Information→ACX (http://www.mitsui-kinzoku.co.jp/project/hakumaku/03/index.html)

### SUMMARY

Each disclosure of the above-mentioned Patent Documents and Non-patent Documents are incorporated herein by reference. Analyses of the related arts by the present invention will be given below.

Each of Patent Documents 1 to 4 and Non-patent documents 1 and 2 discloses the Al-alloy-based material that can be directly and electrically connected to the transparent electrode layer and/or the semiconductor layer.

Each of Patent Documents 1 to 4 and Non-patent documents 1 and 2, however, does not describe or suggest a technical problem about contact hole formation caused by the Al alloy material.

Patent Document 5 discloses electrical connection of a contact hole in a liquid crystal display pixel portion using the interlayer connection material in the liquid state.

Patent Document 5, however, does not specify electrical connection of a gate terminal hole portion or a data terminal hole portion.

Now, a description will be directed to a problem encountered when the disclosed technique of Patent Document 5 has been applied to the gate terminal hole portion or the data terminal hole portion.

In the gate terminal hole portion or the data terminal hole portion of a display device, TCP (Tape Carrier Package) bumps (terminal) face the gate terminal hole portion or the data terminal hole portion with an ACF (Anisotropic Conductive Film) sandwiched therebetween. Then, it is known that this ACF has moisture permeability, and moisture in the air readily passes through the ACF.

For that reason, in the case of a structure in which the interlayer connection material and the pixel electrode are both exposed on a top surface and contact to each other, a local battery is produced at a contact boundary between the interlayer connection material and the pixel electrode. One of metals of the interlayer connection material and the pixel electrode is thereby readily corroded. Patent Document 5 presents a “dispersion solution containing Ag” that is classified into an active metal as the interlayer connection material in paragraph [0030].

As described above, a specific description about the gate terminal hole and the data terminal hole cannot be identified from the specification of Patent Document 5, and suggestion of the technical problem about metal corrosion is difficult to identify.

The present invention has been made in view of the above-mentioned problems. A main object of the present invention is to provide a display device including a contact hole structure capable of reducing a resistance of electrical connection between an upper metal film and a lower metal film for a contact hole represented by a gate terminal hole, a data terminal hole, a pixel connection hole, or the like and enhancing reliability of the contact hole structure.

The present invention provides a display device in which, by applying the contact hole structure and a fabrication method of the contact hole structure that achieve the above-mentioned object, a metal film of an Al-alloy-based material or the like that can be directly and electrically connected to a transparent electrode layer and/or a semiconductor layer but is inferior in corrosion resistance can be used, without arranging a cover layer, for example.

According to the present invention, there is provided a display device comprising a contact hole, the contact hole including:

a lower layer metal film disposed on a substrate;

an insulating film disposed on the lower layer metal film, the insulating film having an opening;

an interlayer connection layer formed by solidifying a conductive liquid material disposed extending to cover at least the lower layer metal film exposed by the opening and an edge portion of the insulating film at the opening; and

an upper layer metal film disposed on the interlayer connection layer, the upper layer metal film being extended over a coverage boundary region of the interlayer connection layer to come in contact with the insulating film;

a film thickness of the lower layer metal film exposed by the opening being thinner than a film thickness of the lower layer metal film not exposed by the opening. According to the present invention, there is provided a display device in which the conductive liquid material is disposed in a desired arbitrary position by an inkjet method, or an offset printing method.

According to the present invention, the reduction of resistance and high reliability of electrical connection between an upper metal film and a lower metal film of a contact hole can be achieved. The contact holes may be represented by a gate terminal hole, a data terminal hole, a pixel connection hole, and so forth. According to the present invention, by applying the structure of the contact hole, there can be provided a display device using a film of a metal that is rather inferior in corrosion resistance and is typified by an Al-alloy-based material which can be directly and electrically connected to a transparent electrode layer and/or a semiconductor layer, without arranging a cover layer, for example.

Still other features and advantages of the present invention will become readily apparent to those skilled in this art from the following detailed description in conjunction with the accompanying drawings wherein only exemplary embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIGS. 1A and 1B to 1D are a plane view and sectional views showing a fabrication method and a structure of a TFT substrate in a first example of the present invention;

FIGS. 2A and 2B to 2D are a plane view and sectional views showing a fabrication method and a structure of the TFT substrate in the first example of the present invention;

FIGS. 3A and 3B to 3D are a plane view and sectional views showing a fabrication method and a structure of the TFT substrate in the first example of the present invention;

FIGS. 4A and 4B are sectional views each showing a gate terminal hole in the first example of the present invention;

FIGS. 5A and 5B are sectional views each showing a gate terminal hole in a second example of the present invention;

FIGS. 6A and 6B are sectional views each showing a gate terminal hole in a third example of the present invention;

FIGS. 7A and 7B are sectional views each showing a gate terminal hole in a fourth example of the present invention;

FIGS. 8A and 8B to 8D are a plane view and sectional views showing a fabrication method and a structure of a TFT substrate in a related art of the present invention;

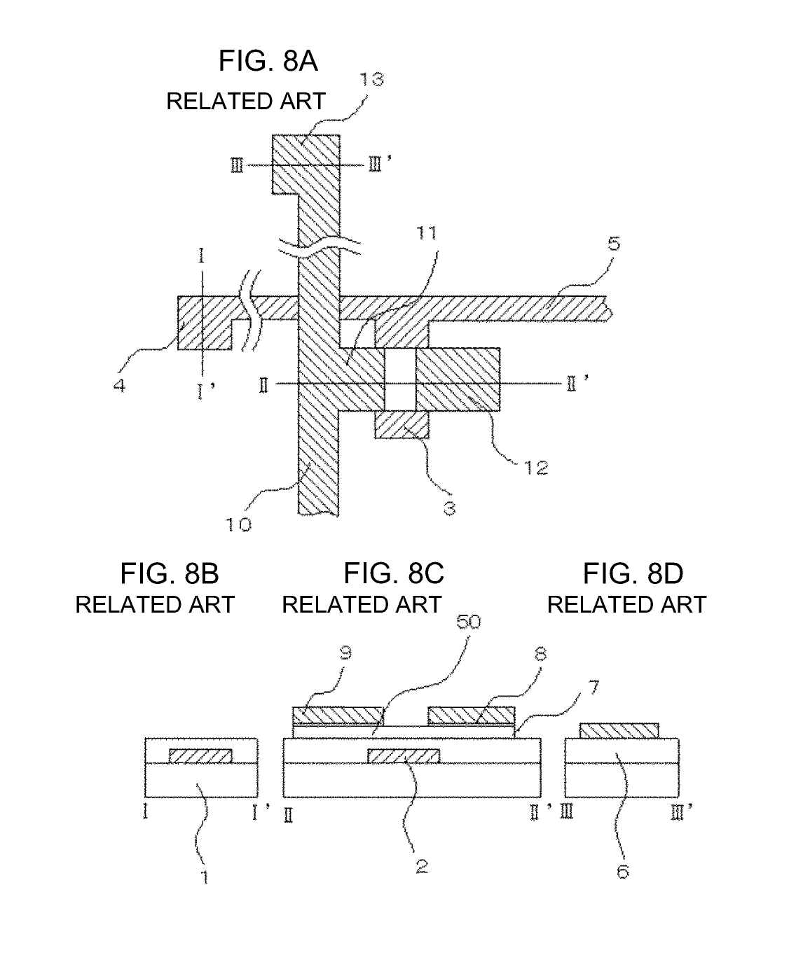

FIGS. 9A and 9B to 9D are a plane view and sectional views showing a fabrication method and a structure of the TFT substrate in the related art of the present invention;

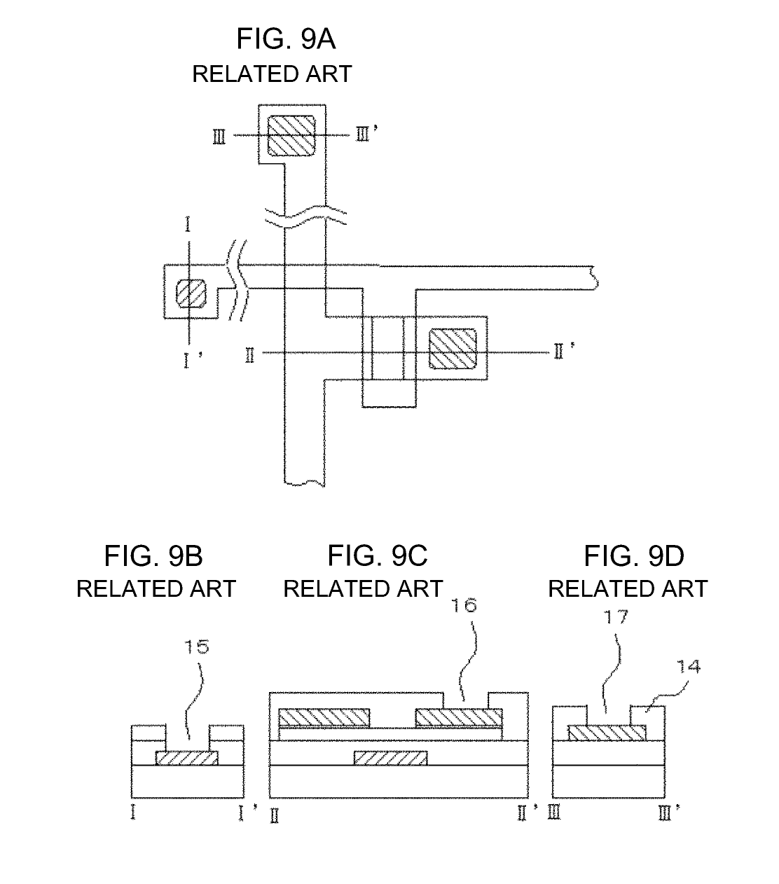

FIGS. 10A and 10B to 10D are a plane view and sectional views showing a fabrication method and a structure of the TFT substrate in the related art of the present invention;

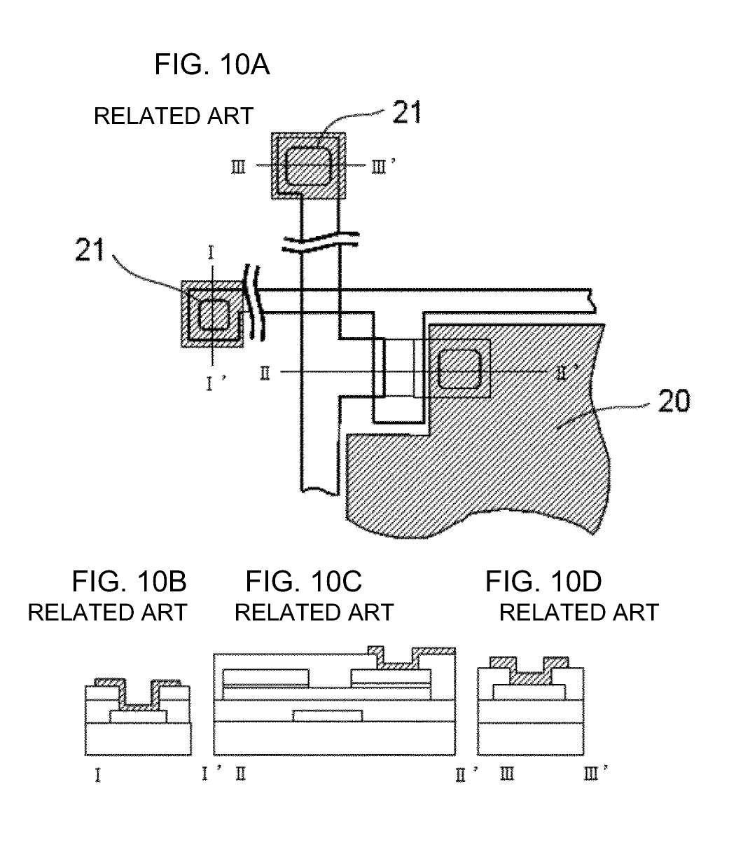

FIG. 11 is a sectional view showing a gate terminal hole in a related art; and

FIGS. 12A and 12B are respectively a plane view and a sectional view each showing a connection hole in Patent Document 5.

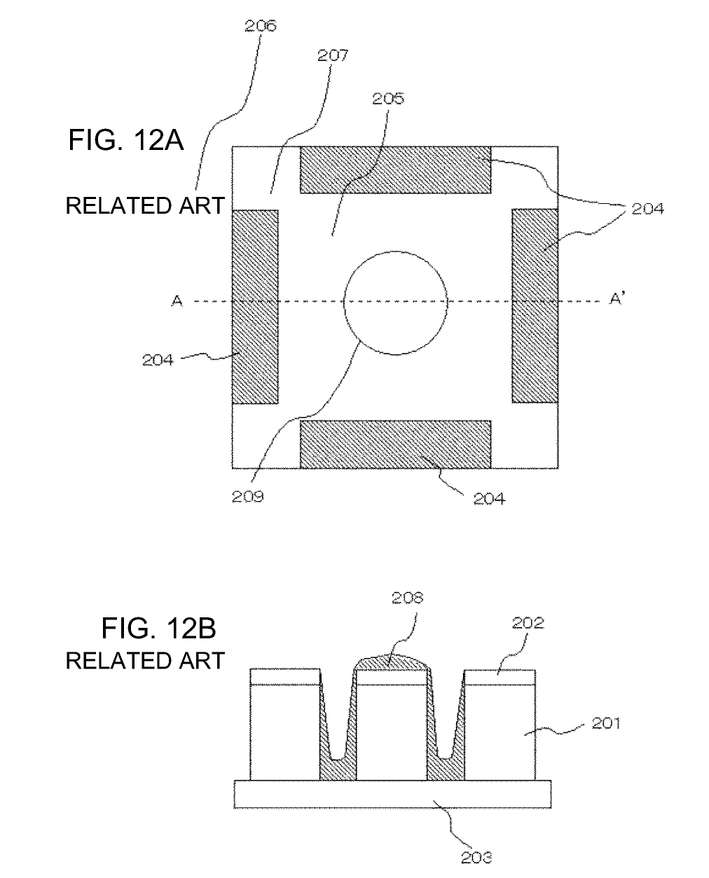

### PREFERRED MODES

In accordance with one of exemplary embodiments of the present invention, in a connection structure for a contact hole, there is provided a conductive liquid material which extends to cover an entire surface of a lower layer metal film exposed by an opening of an insulating film and at least a part of an edge portion of the opening of the insulating film. Then the conductive liquid material is solidified to form an interlayer connection layer (film). On the interlayer connection layer, there is disposed an upper metal film which extends over the coverage region covered by the interlayer connection layer. Therefore, the surface shape of the interlayer connection layer can be set to have a smooth curved surface (also referred to as a curved line, because the sectional shape of the surface is a curved line). For this reason, the number of voids of the upper layer metal film disposed on the interlayer connection layer drastically decreases. As a result, an electrical connection resistance between the upper layer metal film and the lower layer metal film can be reduced, and an increase in reliability of the contact hole can also be achieved.

An edge angle of a coverage boundary of the interlayer connection layer may be set to be low. To this end, preferably, the conductive liquid material may be selected in consideration of the cohesive force of the conductive liquid material and wettability of the conductive liquid material against the insulating film. When an amount of a solvent contained in the conductive liquid material is increased, for example, an amount of volume contraction at a time of solidification increases. The surface shape of the interlayer connection layer can be formed to be shaped in a more curved-line, and the edge angle of the coverage boundary can be further reduced. With this arrangement, void occurrence in the upper layer metal film located on the coverage boundary is made further difficult to take place.

As the conductive liquid material, a material which solidifies at a temperature less than or equal to a maximum temperature to which the material is exposed in a period from start of manufacture of a TFT substrate to completion of a display device may be selected. More preferably, a step where the maximum temperature is attained is set to a step before the conductive liquid material is disposed. With this arrangement, a hillock which may protrude through the interlayer connection layer from the lower layer metal film does not grow on the lower layer metal film. Thus, void formation in the upper layer metal film caused by the hillock on the lower layer metal film can be avoided.

In the process of solidifying the conducting liquid material, pressure reduction should be combined for use with heating. With this arrangement, reduction of a heating period of time and lowering of temperature can be achieved.

A material that dissolves a damaged layer should be selected as the conductive liquid material. With this arrangement, the damaged layer on the surface of the lower layer metal film can be diffused into the conductive liquid material. Thus, good electrical connection can be obtained.

Further, the lower layer metal film may be slightly etched before the conductive liquid material is disposed. With this arrangement, the damaged layer on the surface of the lower layer metal film can be removed. Good electrical connection can be thereby obtained.

The upper layer metal film may be formed by sputtering. With this arrangement, a mixed layer composed of a mixture of the upper layer metal film and the insulating film can be formed.

More preferably, the insulating film may be formed of an organic insulating film, and the upper layer metal film may be formed on the insulating film by sputtering. With this arrangement, a more reliable mixed layer composed of a mixture of the upper layer metal film and the insulating film can be formed. An increase in the reliability of the contact hole can be achieved by the mixed layer.

### First Example

In order to describe the above-mentioned exemplary embodiment of the present invention in further detail, a first example of the present invention will be described, while illustrating from among display devices a liquid crystal display device using inverted staggered-type TFTs.

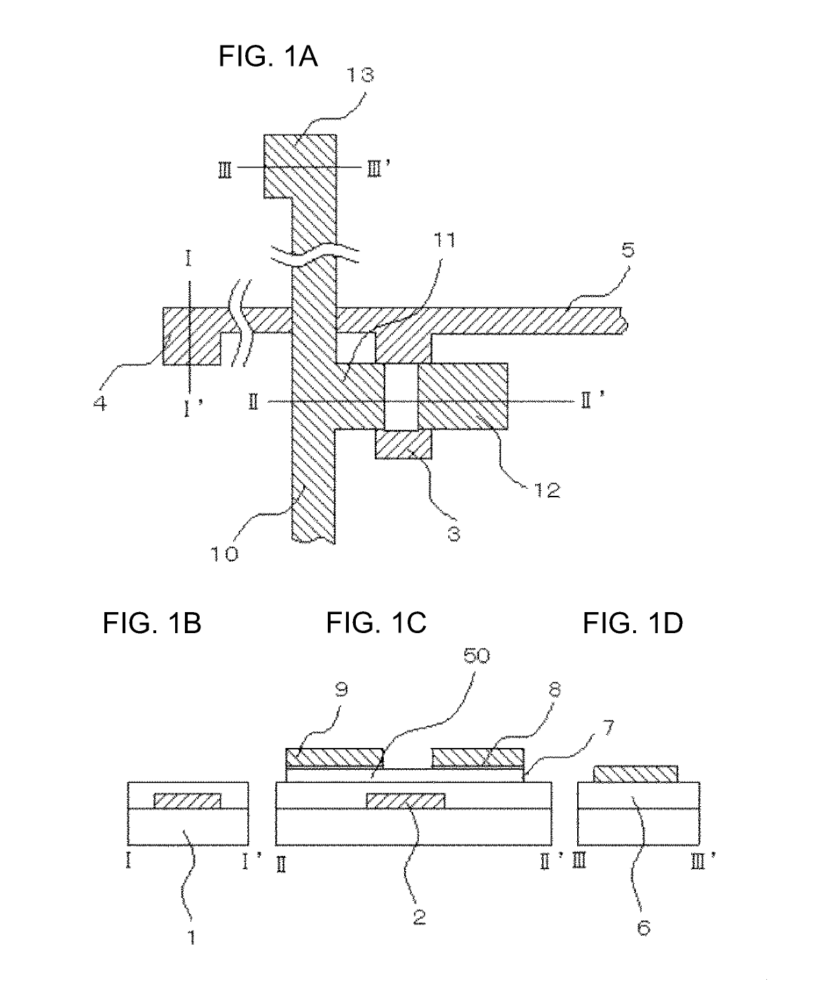

First, a fabrication method and a structure of a TFT substrate will be described in detail using FIGS. 1 to 3.

Each of FIGS. 1A, 2A, and 3A shows a plane of one of a plurality of display pixels formed in the form of a matrix, a gate terminal portion, and a data terminal portion in a schematic diagram. FIGS. 1B, 2B, and 3B respectively show sections of the gate terminal portion taken along I-I′ lines of FIGS. 1A, 2A, and 3A, in schematic diagrams. FIGS. 1C, 2C, and 3C respectively show sections of the pixel portion taken along II-II′ lines of FIGS. 1A, 2A, and 3A, in schematic diagrams. FIGS. 1D, 2D, and 3D respectively show sections of the data terminal portion taken along III-III′ lines of FIGS. 1A, 2A, and 3A, in schematic diagrams. In FIGS. 1 to 3, reference numeral 1 denotes a transparent substrate, reference numeral 2 denotes a first metal film (lower layer metal film), reference numeral 3 denotes a gate electrode, reference numeral 4 denotes a gate terminal, reference numeral 5 denotes a gate interconnect, reference numeral 6 denotes a first insulating film, reference numeral 7 denotes a semiconductor film, reference numeral 8 denotes a contact film, reference numeral 9 denotes a second metal film (upper layer metal film), reference numeral 10 denotes a data interconnect, reference numeral 11 denotes a source electrode, reference numeral 12 denotes a drain electrode, reference numeral 13 denotes a data terminal, reference numeral 14 denotes a second insulating film, reference numeral 15 denotes a gate terminal hole, reference numeral 16 denotes a pixel connection hole, reference numeral 17 denotes a data terminal hole, reference numeral 20 denotes a pixel electrode, reference numeral 21 denotes a terminal protection pattern, and reference number 22 denotes an interlayer connection film.

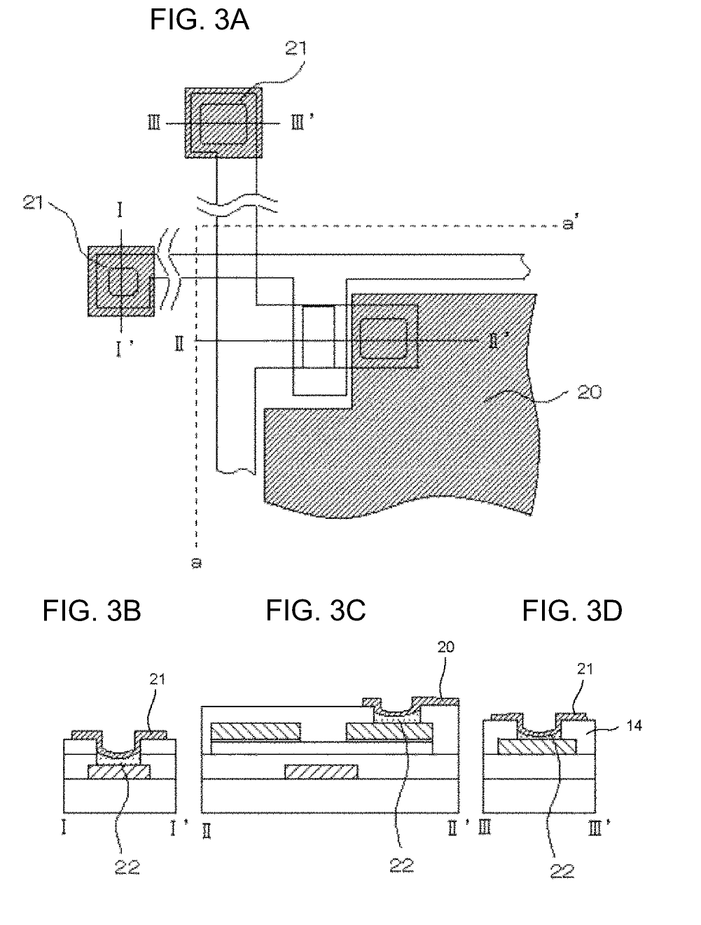

First, the first metal film 2 described in each of Patent Documents 1 to 4 and Non-patent Documents 1 to 2, capable of being electrically connected to a film that forms the pixel electrode 20 (refer to FIG. 3) is deposited the transparent substrate 1, using a magnetron sputtering device.

In this example, a non-alkali glass is illustrated for the transparent substrate 1. The substrate may also be the one having more flexibility, such as a film having heat resistance and chemical resistance. Further, in case a reflection-type liquid crystal display device is produced, the transparent substrate does not necessarily need to be employed.

Next, using known lithography, a resist is coated, exposed to light, and developed to form a resist pattern, and the first metal film 2 is wet etched by a mixed acid etchant composed of phosphoric acid, nitric acid, acetic acid, and water. The resist is thereby removed to form the gate electrode 3, gate terminal 4, and gate interconnect 5.

A positive resist that can be dissolved in a base solution of a novolac-based resin may be preferably used. A 2.38% aqueous solution of TMAH (tetra methyl ammonium hydroxide) may be used as a developing solution. Preferably, a commonly used mixed solution of DMSO (dimethyl solfoxide) and MEA (monoethanolamine) may be used as a stripping solution. The same resist, same developing solution, and same stripping solution are used in a known photolithography step as well, which will be described later. In the following description, a description about the resist, developing solution, and stripping solution will be omitted.

Next, a cleaning process mainly for removing particles and impurities is executed as necessary. The exposed first metal film is an alloy mainly composed of Al, which is an amphoteric metal. Thus, the first metal film has low chemical resistance and is easy to dissolve (which means that the first metal is highly corrosive). For that reason, it is not desirable to use an acid or base solution for this cleaning process, and a neutral surface active agent solution, for example, may be used.

Secondly, the first insulating film 6 made of silicon nitride (hereinafter referred to as SiNx), the semiconductor film 7 made of a-Si, and the contact film 8 made of n⁺-a-Si in which phosphorous has been doped are successively deposited using plasma CVD, without breaking a vacuum.

Next, using a known photolithography method, a resist pattern is formed, the contact film 8 and the semiconductor film 7 are etched to remove the resist, thereby forming an island pattern 50. This island pattern 50 is formed over the gate electrode 3 with the first insulating film 6 sandwiched between the gate electrode 3 and the island pattern 50.

In this example, the first insulating film 6 is set to consist of a single layer of the SiNx film. The first insulating film 6 may be a laminated layer film. By using the laminated layer film, the number of pin holes in the first insulating layer 6 can be reduced. The first insulating film 6 is not limited to the SiNx film. A different inorganic insulating film such as a SiOx film may be used. When the SiOx film is used, TFT characteristics can be stabilized. Further, an organic insulating film such as an acryl-based film or a novolac-based film may be used as the first insulating film 6. By selecting the organic film in addition to the inorganic film, the first insulating film 6 can be selected from a wide range of permeability.

Thirdly, the second metal film 9 which is described in each of Patent Documents 1 to 4 and Non-patent Documents 1 to 2 is deposited, using the magnetron sputtering device, after cleaning.

Then, using a known photolithography method, a resist pattern is formed, the second metal film 9 is etched by the etchant which is the same as that for the first metal film 2 to remove the resist. The data interconnect 10, source electrode 11, drain electrode 12, and data terminal 13 are thereby formed.

Next, a cleaning process mainly for removing particles and impurities is executed as necessary. The exposed second metal film 9 is an alloy mainly composed of Al, which is the amphoteric metal. Thus, the second metal has low chemical resistance and is easy to dissolve. For that reason, it is not desirable to use an acid or base solution for this cleaning process, and a neutral surface active agent solution, for example, may be used.

At least one of the source electrode 11 and the drain electrode 12 is formed to come into contact with the contact film 8 from which the island pattern is formed. However, the second metal film 9 may diffuse into the contact film 8. Then, depending on the demanded performance of the device, the condition where the at least one of the source electrode 11 and the drain electrode 12 is formed to come into contact with the contact film 8 may not be satisfied. In this case, a film of Mo, Cr, Ti, or an alloy thereof or the like may be disposed under the second metal film 9, as a diffusion prevention film.

With this arrangement, the diffusion of the second metal film 9 formed of the alloy film mainly composed of Al into the contact film 8 to a certain level or more to cause deterioration of the transistor characteristics can be prevented.

When an Mo film and a film of an alloy of Mo capable of being removed by the mixed acid etchant that is the same as for the second metal film 9 are used as this diffusion prevention film, there is an advantage that the number of etching steps is not increased. The mixed acid etchant is composed of phosphoric acid, nitric acid, acetic acid, and water.

Fourthly, before the resist pattern of the second metal film 9 is removed, or after the resist pattern of the second metal film 9 has been removed, the contact film 8 is removed to expose the semiconductor film 7. A channel area is thereby formed between the source electrode 11 and the drain electrode 12.

If a part of the semiconductor film is also removed at this time, an off-characteristic of a transistor can be improved, which is preferable.

Then, when channel formation is performed using a resist as a mask, the resist is removed (refer to FIG. 1, for the above description).

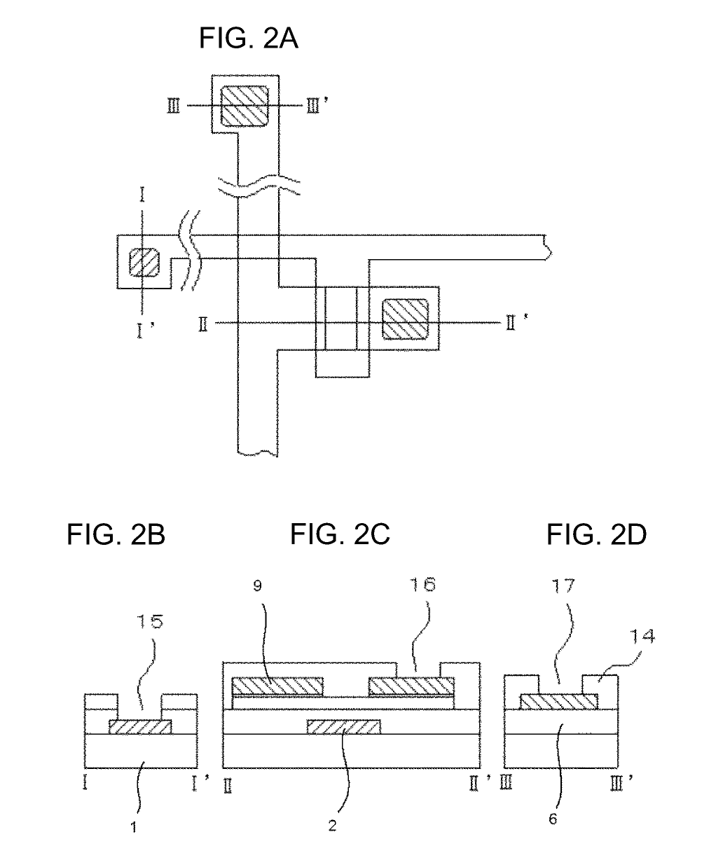

Fifthly, the second insulating film 14 constituted from a SiNx film is formed using plasma CVD. Then, using a known photolithography method, a resist pattern is formed, the first insulating film 6 is also etched, together with the second insulating film 14, and the resist is removed to form openings such as the gate terminal hole 15, pixel connection hole 16, and data terminal hole 17 that will become contact holes (as shown in FIGS. 2B, 2C, and 2D).

In this example, the second insulating film 14 is set to one layer of the SiNx film. The second insulating film 14 may be a laminated layer film, like the first insulating film 6. The second insulating film 14 is not limited to the SiNx film, and may be an inorganic insulating film or an organic insulating film.

Problems encountered in the stripping step that will become challenges in particular in the present invention will be specifically described, in order to facilitate understanding of the present invention.

A first problem is that a commonly-used, preferable stripping solution in the fabrication process of the TFT substrate is the mixed solution of DMSO and MEA. The mixed solution, when mixed with water, has a property in which MEA is separated from this mixed solution, and exhibits a strong basicity.

The substrate from which the resist has been removed using the stripping solution in the stripping step is washed by water so as to remove the stripping solution from the surface of the substrate. For that reason, at a time of this water washing process, MEA and water are mixed to produce a base solution on the substrate.

In a related art device as well in which a cover film has been disposed, the problem of dissolution of an Al—Nd film by the base solution is present in stripping steps in which the Al—Nd film has been exposed from the cover film (that are a stripping step after a first metal film has been patterned and a stripping step after a second metal film has been patterned, described in the [background art]. In these steps, an upper portion of the pattern is covered by the cover film, but the Al—Nd film is exposed at an edge portion of the pattern.). Thus, treatment of the substrate by IPA (isopropyl alcohol) or DMSO, for example, is performed between the process using the stripping solution and the water washing process, thereby diluting the stripping solution (performing a replacement process).

In this example, no cover film is disposed on both of surfaces of the first metal film 2 and the second metal film 9. Thus, the replacement process which is more reliable than for the related art structure in which the cover film is disposed is demanded.

In this example, as in the [background art], the stripping step where the first metal film 2 is exposed is a stripping step after the first metal film has been patterned, and the stripping step where the second metal film 9 is exposed is a stripping step after the second metal film has been patterned. In the present example, no cover film is disposed. Thus, a stripping step after the opening has been patterned is newly added. In this stripping step, the first metal film 2 and the second metal film 9 are both exposed.

In the stripping step after the first metal film 2 has been patterned and the stripping step after the second metal film 9 has been patterned, the first insulating film 6 and the second insulating film 14 are respectively deposited after completion of the stripping steps. Thus, even if the metal film has been dissolved in each of the stripping step, the insulating film is deposited with adhesion on a metal pattern after dissolution.

However, in this stripping step after the openings have been patterned, the first insulating film 6 is already deposited on the first metal film 2, and the second insulating film 14 is already deposited on the second metal film 9. For this reason, when each of the metal films is dissolved, a lower surface end of an edge portion of the insulating film will project from each of the first metal film 2 and the second metal film 9.

Hence, in this stripping step, the replacement process of the stripping solution that is more reliable than in the stripping step after the first metal film 2 has been patterned and the stripping step after the second metal film 9 has been patterned is demanded (the problem of this projection of the lower surface end of the edge portion of the insulating film will be described later in detail).

Further, a second problem which renders the replacement process of the stripping solution more important in this example will be described below.

The Al—Nd film (having a large connection resistance value) which cannot be directly and electrically connected to a film made of ITO or the like which forms a pixel electrode and the Al alloy which can be directly and electrically connected to ITO in this example are both alloy films mainly composed of Al. However, these alloy films are different from the film made of ITO or the like which forms the pixel electrode in terms of electrical connectivity. This difference is estimated to be caused by a difference of deposition states of alloy materials or oxidation degrees of surfaces of the films.

An aluminum oxide film is chemically more stable and more highly chemically resistant than aluminum, but has a very large electrical resistance. Results of a resistance to base solution test will be shown below.

As specimens, an A-Nd film produced by Kobelco Research Institute, Inc., an Al—Ni—La film produced by Kobelco Research Institute, Inc., and an ACX film produced by Mitsui Mining & Smelting Co., Ltd. are respectively formed on glass at 150° C. using the magnetron sputter, and are cut into a size capable of being put into a beaker filled with the solution.

A resistance to base solution test may be handled and carried out in the actual stripping step. However, the degree of separation (degree of basicity) in the stripping step is determined by a mixture ratio between the stripping solution and water. Thus, comparison and study in the actual stripping step are not suitable. The reason for that is as follows. In the stripping step, water is successively supplied to the substrate with the stripping solution deposited thereon by a method of shower or the like. During supply of water, the degree of basicity is successively changed, and the mixture ratio is not always constant among all the samples. Further, DMSO in the stripping solution is highly hygroscopic.

For that reason, the 2.38% aqueous solution of TMAH is diluted with water to approximately three times its original volume, and each specimen is immersed in the diluted solution to measure the etching rate of each film, for comparison. The 2.38% aqueous solution of TMAH has a smaller basicity than a solution obtained by mixing the stripping solution with water, but is commonly and preferably used as the developing solution in manufacture of the display device. With this method, the object of the resistance to base solution test can be achieved.

It was found from results of the tests that the Al—Ni—La film and the ACX film both had a dissolution rate that was approximately eight to 10 times that of the Al—Nd film. This means that the Al—Ni—La film and the ACX film are inferior to the Al—Nd film in the degree of base resistance.

Since compositions of purchased Al—Ni—La alloy and ACX cannot be readily changed, a resistance to base solution test was carried out using an Al—Ni alloy of which a composition can be readily changed. The property of a metal capable of being directly and electrically connected to ITO was thereby clarified.

Specimens for the test are formed by the magnetron sputter, and each specimen is cut to a size capable of being put into a beaker, for adjustment. The composition of the alloy was varied so that a small piece of Ni occupies 2%, 3%, and 5% of the area of an AL target.

The larger the content ratio of Ni of the Al—Ni film of which the composition was varied is, the more a connection resistance with the ITO was reduced.

Further, in the resistance to base solution test, it was confirmed that the more the content ratio of Ni was increased in the specimen, the more the etching rate of the specimen was increased.

It is seen from these results of the test that the more connectivity between the ITO and the Al—Ni alloy is ensured, dissolution resistance against the base solution deteriorates. That is, it can be understood that the better electrical connection with the ITO can be made, the Al—Ni alloy specimen tends to be corroded by the base solution (which means that the Al—Ni alloy specimen is inferior in corrosion resistance), and more reliable replacement process is demanded in the stripping step.

In recent years, with a trend toward reduction of resistance of a TFT interconnect material that forms a display device, copper and an alloy of copper are being put into practical use. These metals, however, also have a similar problem.

Sixthly, Au nano ink is disposed in the openings of the gate terminal hole 15, pixel connection hole 16, and data terminal hole 17, and the like, using piezo inkjet, as an conductive liquid material (“conductive liquid material” being referred to as a material which does not necessarily have electrical conductivity when it is in a state having fluidity, but has electrical conductivity in a solidified state), left standing to flow, and is then heated. The solvent of the ink is thereby evaporated, and the resultant material is then solidified for use as the interlayer connection film 22.

The conductive liquid material may be optionally disposed in a desired position, and thermal inkjet, an offset printing device, or the like may also be used.

For solidification of the conductive liquid material, pressure reduction may be performed before heating so as to accelerate the evaporation speed of the solvent. Alternatively, heating and pressure reduction may be simultaneously performed. By performing pressure reduction, the evaporation speed of the solvent can be accelerated. A heating period of time and a heating temperature can be thereby reduced. This makes it difficult for a conductive material mixed in the conductive liquid material to be oxidized.

When a material that solidifies by heating is selected as the conductive liquid material, the operation is easy and preferable. However, the conductive liquid material may be solidified by a laser beam, an ion beam, or the like. A method of solidifying the conductive liquid material is not limited to heating.

An ink or a paste containing a metal such as Ag, Cu, Ni, Pt, Pd, or ITO as well as Au may be employed as the conductive liquid material. A binder material may be mixed as necessary.

Further, preferably, a material that solidifies at a temperature less than or equal to a maximum temperature exposed in a period from start of manufacture of the TFT substrate to completion of the display device is selected as the conductive liquid material.

To achieve that purpose, a conductive liquid material whose solvent evaporates at a temperature less than or equal to the maximum temperature may be selected. Further, when the binder material is contained, preferably, a material which evaporates at a temperature less than or equal to the maximum temperature is selected as the binder material.

As an example of the preferable conductive liquid material, a conductive liquid material without including the binder material, in which Au nanoparticles having a mean value of a particle diameter on the order of 5 nm have been dispersed into the solvent of the conductive liquid material, may be disclosed. The above-mentioned conductive liquid material may be heated to approximately 200° C. to evaporate the solvent, for solidification. Then, the interlayer connection film 22 may be thereby formed. The solvent for dispersion, into which the Au nanoparticles are dispersed, can be selected from common organic solvents. Thus, under the condition of 200° C., various solvents can be selected.

When the Au particle size is reduced to a nano level, the Au nanoparticles are activated, so that a melting point of the Au nanoparticles is reduced. For that reason, it becomes possible to cause secondary particles to grow at a low heating temperature.

That is, when the conductive liquid material containing the conductive material of the small particle size of the nano level is used, the conductive particles come into contact to one another when the solvent is volatilized by heating. Then, not only the conductive particles have electrical conductivity, but also primary particles of the conductive material that have been dispersed into the conductive liquid material combine to one another to cause the secondary particles to grow. An interlayer connection layer having a low volume resistance, of which the film becomes denser, can be formed.

The reason why it is preferable that the conductive liquid material which solidifies at a temperature less than or equal to the maximum temperature to which the conductive liquid material is exposed in the period from start of manufacture of the TFT substrate to completion of the display device be selected is as follows. An Al alloy film capable of being directly and electrically connected to the film that forms the pixel electrode is premised on that the formation of hillock is suppressed. The main component of the Al alloy film, however, is Al. Thus, the complete elimination of the hillock is difficult.

The hillock grows, depending on a maximum heating temperature. Assume that the maximum temperature is attained in the step where the conductive liquid material is solidified or a step thereafter. Then, the hillock that has grown from the first metal film or the second metal film may break through a surface of the interlayer connection film 22 to grow. Then, when the hillock breaks through the surface of the interlayer connection film 22, a void will be formed in the terminal protection pattern 21, which will be described later. A problem caused by the void will be described later in detail.

The step where the maximum temperature is attained in the fabrication process of the liquid display device is generally the step where the first insulating film 6, semiconductor film 7, and contact film 8 are successively deposited or the CVD step where the second insulating film 14 is deposited. The maximum temperature is approximately 350° C. or higher. The solvent contained in the conductive liquid material may be evaporated at a temperature less than or equal to the maximum temperature, for solidification.

Seventhly, a transparent conductive film made of ITO is deposited over an entire surface of the substrate at 150° C. to cover the openings of the second insulating film 14, gate terminal hole 15, pixel connection hole 16, and data terminal hole 17. Then, using a known photolithography method, a resist pattern is formed, and the resist is etched and is then stripped. Then, the terminal protection pattern 21 is formed over coverage regions of the interlayer connection film 22 to cover the gate terminal hole 15 and the data terminal hole 17. The pixel electrode 20 is formed over a coverage region of the interlayer connection film 22 to cover the pixel connection hole 16. The contact holes are thereby completed, and the substrate for a-Si TFTs of the inverted staggered type is completed (as shown in FIG. 3).

Preferably, a film of IZO (indium zinc oxide film), a film of Sno (tin oxide film), or the like may be used for the transparent conductive film, in addition to the illustrated film of ITO.

Next, a method of manufacturing a liquid crystal display panel in this example will be described.

First, a polyimide is coated on the completed TFT substrate, baked, and rubbed, thereby forming an alignment film. Polyimides in general can be sufficiently baked at 200° C.

Further, a light shielding layer and a color layer are disposed as necessary. A Polyimide is coated on an opposing substrate as well on which a transparent conductive film of ITO or the like is disposed as an opposing electrode, baked, and rubbed to form an alignment film.

Secondly, surfaces of the TFT substrate and the opposed substrate with the alignment films disposed thereon are made to face each other. Then, a liquid crystal material containing a chiral material is interposed in a gap between the TFT substrate and the opposing substrate.

The gap (cell gap) between both of the substrates is held by an in-plane spacer within a display surface and a sealant outside the display surface, which surrounds the display surface. There are various types of sealants such as a thermosetting type, a photo- and thermo-setting type, and a photosetting type. Even if the thermosetting type that needs a high temperature, such as an acryl-based sealant, is used, the sealant is sufficiently set by baking at a temperature on the order of 200° C. (A location where the sealant is disposed is written by a broken line a-a′ in FIG. 3. The opposing substrate is positioned on a pixel electrode side of the broken line. The liquid crystal material is sealed in the gap between the TFT substrate and the opposing substrate. No components are disposed above a region outside the broken line, and the region is exposed to the air.)

Thirdly, an optical film and the like such as a retardation film, a polarizing film are attached to a substrate in which the TFT substrate and the opposing substrate are attached with liquid crystal sealed in therebetween, as necessary. The liquid crystal panel of a TN (Twisted Nematic) type is thereby completed.

Next, a fabrication method of the liquid crystal device in this example will be described.

In the liquid crystal panel completed as described above, the gate terminal hole 15 covered with the terminal protection pattern 21 and the data terminal hole 17 covered with the terminal protective pattern 21 are provided on the TFT substrate with exposure to an air.

First, the terminal protection pattern 21 of the gate terminal hole 15 and the data terminal hole 17 on the TFT substrate and TCP (Tape Carrier Package) bumps (terminals) with interconnects are bonded by an ACF (Anisotropic Conductive Film) made of an organic resin in which Au particles or the like have been dispersed.

Secondly, the other ends of the interconnects formed in the TCP are connected to a circuit such as a drive circuit which drives the liquid crystal panel, and the like. The circuit and the like may be herein connected to the TCP before bonding the terminal holes and the bumps by the ACF.

Thirdly, a front chassis including an opening which defines the display surface, a backlight, a light guide plate, and a rear chassis which holds the back light and the light guide plate are disposed. The liquid crystal device is thereby completed.

Herein, a method of connection using the TCP was illustrated. The bumps may be the ones of COG (Chip On Glass) or the like. The liquid crystal display device may have a structure in which the terminal protection pattern 21 of the gate terminal hole 15 and the data terminal hole 17 mutually face at least the terminals electrically connected to the drive circuit, and these pattern and terminals are mutually bonded by the ACF or the like.

Next, a feature portion of the first example will be described in further detail. Herein, the description will be given, focusing on a step related to the step of arranging the conductive liquid material over the substrate.

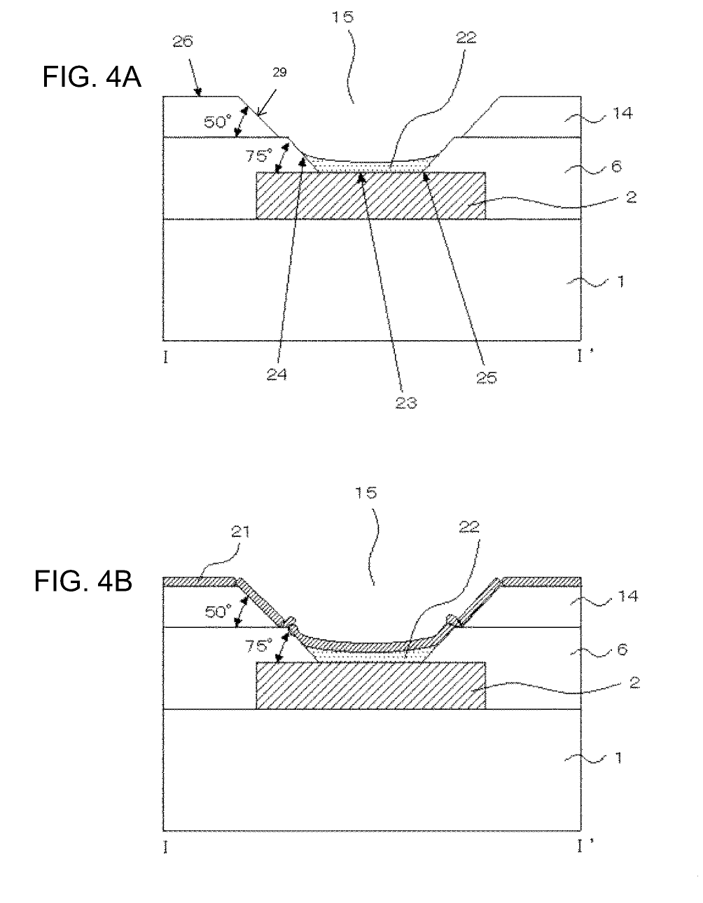

Compared with the pixel connection hole 16 and the data terminal hole 17, the first insulating film 6 is excessively laminated in the opening of the gate terminal hole 15. For that reason, the description will be given, taking the gate terminal hole 15 as a typical example and using sectional views of FIGS. 4A and 4B. Each of FIGS. 4A and 4B shows a section of a region corresponding to a region taken along the line I-I′ of FIG. 1.

The interlayer connection film 22 is disposed extending across an intersection (exposed surface/edge portion intersection 25) between a first metal film exposed surface 23 located at the opening of the gate terminal hole 15 and a first insulating film edge portion 24 so that the interlayer connection film 22 covers both of the first metal film exposed surface 23 and a part of the first insulating film edge portion 24.

The conductive liquid material can flow when disposed at the opening. Thus, the conductive liquid material flows in such a manner that its surface (surface opposite to the side of the first metal film exposed surface) assumes a shape of a gentle curve.

Then, by heating the conductive liquid material, the solvent mixed with the conductive liquid material evaporates with the shape of the conductive liquid material maintained to a certain degree. Volume contraction thereby occurs, and the conductive liquid material solidifies.

For that reason, on the surface of the solidified interlayer connection film 22 (surface opposite to the side of the first metal film exposed surface), there are no such discontinuous point as the exposed surface/edge portion intersection 25 at which the exposed surface 23 and the edge portion 24 linearly intersect. The surface of interlayer connection film 22 after solidification assumes a shape of a gentle concave curve.

Further, the interlayer connection film 22 gradually gets thinner toward its coverage boundary that covers the first insulating film edge portion 24 (as shown in FIG. 4A).

Then, the surface shape of the interlayer connection film 22 and an angle of the interlayer connection film 22 at the coverage boundary may be controlled by arbitrarily adjusting the cohesive force of the conductive liquid material, wettability between the conductive liquid material and the first insulating film 6, and the like.

For that purpose, the type of the solvent mixed with the conductive liquid material, the particle size of the conductive material, and an amount of the conductive material relative to the solvent may be adjusted. Addition of a surface active agent is also effective so as to improve the wettability between the conductive liquid material and the first insulating film 6. With this arrangement, the surface shape of the interlayer connection film 22 can be more smoothed, and the angle of the coverage boundary of the interlayer connection film 22 at the first insulating film edge portion 24 can be readily reduced.

Tetradecane or decanol, for example, may be mixed with the solvent of the conductive liquid material. Further, when the edge angle of the coverage boundary is desired to be low, pretreatment is carried out by bringing the first metal film exposed surface 23 and the first insulating film edge portion 24 into contact with each other or exposing the first metal film exposed surface 23 and the first insulating film edge portion 24 before the conductive liquid material and the solvent such as the tetradecane or decanol in a liquid or gaseous state contained in the conductive liquid material are disposed. Then, the conductive liquid material may be disposed at the opening.

A formation state of the interlayer insulating film 22 disposed at the opening can be readily checked by fracturing the substrate and observing a section of the substrate by an SEM (scanning electron microscope) or the like.

A transparent conductive film that will become the terminal protection pattern 21 is formed over the substrate, at the openings for which the interlayer connection film 22 has been formed as described above, using the magnetron sputter, for example.

Then, by performing a known photolithography method, etching and removal process, the terminal protection pattern 21 formed of the transparent conductive film that is the same as for the pixel electrode is disposed, extending to a second insulating film exposed surface 26 across the interlayer connection film 22 and the coverage boundary between the interlayer connection film 22 and the first insulating film edge portion 24 (as shown in FIG. 4B).

Though the terminal protection pattern 21 is configured as described above in this example in order to disclose a preferred method of manufacturing the TFT substrate and the preferred structure of the TFT substrate, the terminal protection pattern 21 is not necessarily limited to the film that forms the pixel electrode 20.

When a metal film that is more stable (corrosion resistant) than the ITO film illustrated in this example, corrosion resistance of a terminal connecting portion will improve. In this case, however, the metal film needs to be a film different from the film that forms the pixel electrode. Thus, the number of deposition steps will increase by at least one time. The terminal protection pattern 21 may also be of a laminated structure.

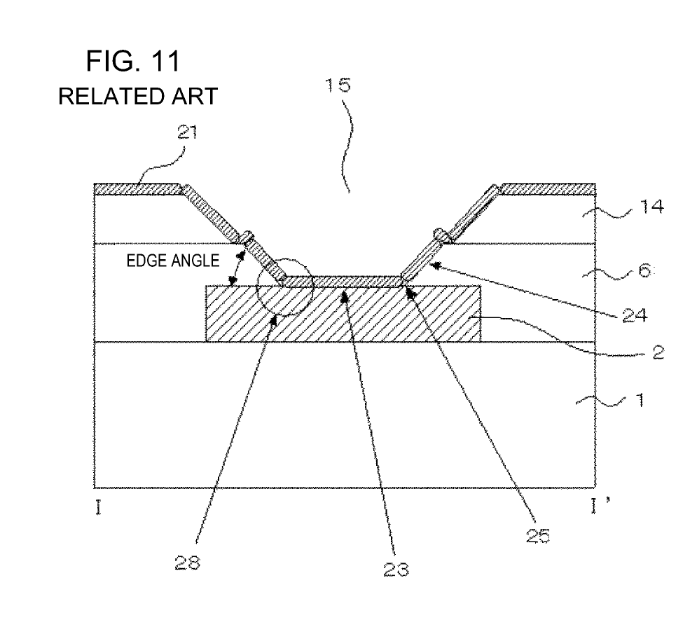

A description will be given using FIG. 11 which shows a related art so as to facilitate understanding of FIG. 4B.

A growth direction of film deposition particles that form a sputtered film depends on a flying direction of the sputtered particles and an angle of the surface of the film with which the sputtered particles collide.

As shown in FIG. 11, orientations of film surfaces of a first metal film exposed surface 23 and a first insulating film edge portion 24 linearly cross at an exposed surface/edge portion intersection 25 and are discontinuously different.

For that reason, deposition particles that form a terminal protection pattern 21 grow in different directions, reflecting the surface shape of a base substrate. A void 28 is thereby created.

The thickness of the ITO film was set to 80 nm in order to identify the angle of a discontinuous intersection at which the void is generated (80 nm being the thickness that is approximately twice the usually set film thickness of a TFT. When the film thickness is set to be thicker, the deposition particles grow in a horizontal direction as well. A grain boundary interval is naturally narrowed. For that reason, the void is difficult to see. However, an increase in the film thickness is not desirable for the display device because transmissivity is reduced). An angle formed between the first metal film exposed surface 23 and the first insulating film edge portion 24 (angle at which a line connecting an edge portion lower end and an edge portion upper end of the first insulating film edge portion 24 crosses a reference line when the first metal film exposed surface 23 is set to the reference line) was varied to check a formation state of the void.

When the angle of discontinuous intersection is 45° or more, the void was clearly observed in an SEM observation.

The description will be kept on by referring back to FIG. 4B. In this example, the film thickness of the interlayer connection film 22 was set to be on the order of 60 nm, for example (the film thickness of the interlayer connection film 22 being set to the thickness of the interlayer connection film 22 located on the metal film exposed surface (in this case, the first metal film exposed surface 23), which is the thickness of a thinnest portion of the interlayer connection film 2 in a direction vertical to the metal film exposed surface).

The thinnest portion of the interlayer connection film 22 was a generally center portion of the gate terminal hole 15.

The film thickness of the first insulating film was set to 400 nm, and the coverage boundary of the interlayer connection film 22 disposed at the first insulating film edge portion 24 was set to approximately 250 nm from the lower surface of the first insulating film 6 in contact with the first metal film 2.

Then, the terminal protection pattern 21 was disposed to cover the entire surface of the interlayer connection film 22 and further extend to the second insulating film exposed surface 26.

ITO was selected for the terminal protection pattern 21, and the film thickness of the terminal protection pattern 21 was set to 40 nm.

As a result of observation of the section of the opening formed as described above, no void was not seen in the terminal protection pattern 21 located over the interlayer connection film 22 and the terminal protection pattern 21 located on the coverage boundary of the interlayer connection film 22.

The angle between the first metal film exposed surface 23 and the first insulating film edge portion 24 at the exposed surface/edge portion intersection 25 in this example was approximately 75°.

When the interlayer connection film 22 is disposed extending over the first metal film exposed surface 23 and the first insulating film edge portions 24 as described above, no void is seen in a range of the interlayer connection film 22 and the first insulating film edge portion 24.

In this example, the interlayer connection film 22 is not disposed across an upper surface end of the first insulating film edge portion. The angle of the upper surface end of the first insulating film edge portion in this example is 105° (180°−75°). A void was seen in this upper surface end.

Further, the film thickness of the second insulating film 14 was set to 250 nm, and the angle of a lower surface end of a second insulating film edge portion 29 was set to approximately 50°. Voids of the terminal protection pattern 21 were seen both in upper and lower surface ends of the second insulating film edge portion 29.

In this example, the coverage boundary of the interlayer connection film 22 was set to the first insulating film edge portion 24. The present invention is not limited to this configuration. The interlayer connection film 22 may be formed by extending the interlayer connection film 22 to the second insulating film edge portion 29.

With this arrangement, occurrence of the voids in the upper surface end of the first insulating film edge portion 24 and a lower surface end of the second insulating film edge portion 29 is eliminated.

In the above description of this example, the fabrication method and the structure of the transmissive type TN liquid crystal display device using the a-Si TFTs of the inverted staggered type were illustrated and described. The present invention may be applied to a liquid crystal display device using a-si TFTs of a forward (non-inverted) staggered type, and may also be applied to a crystalline silicon TFT (c-Si TFT) liquid crystal display device, or a reflective-type TFT display device.

A display method is not limited to a TN (Twisted Nematic) method, and may be a VA (Vertical alignment) method or an IPS (in Plane Switching) method. In the case of the IPS method, the opposing electrode is not disposed on the opposing substrate.

This example is not limited to the liquid crystal display device, and may also be adopted for an organic EL (organic electroluminescence) panel or a PDP (Plasma Display Panel).

When the conductive liquid material is disposed in the opening and the interlayer connection layer is formed between the upper layer metal film and the low layer metal film, as described above, occurrence of a void in the upper layer metal film can be suppressed, so that satisfactory electrical interconnection can be ensured.

### Second Example

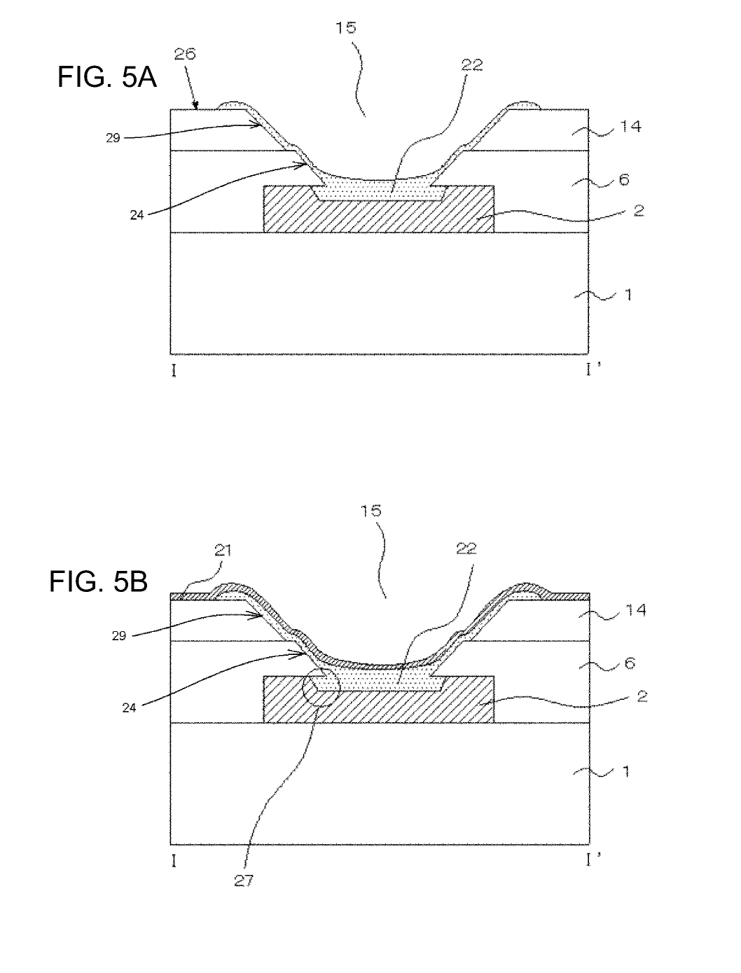

Next, a second example of the present invention will be described using FIGS. 5A and 5B. A sectional view shown in each of FIGS. 5A and 5B is the view of a section in the vicinity of a gate terminal hole 15 as in FIGS. 4A and 4B used in the description of the first example.

A difference from the first example is a coverage region of an interlayer connection film 22. A description will be given, centering on the difference.

In the second example, the interlayer insulating film 22 with a film thickness of 60 nm, for example, is disposed so that the interlayer insulating film extends up to a second insulating film exposed surface 26 across the gate terminal hole 15, for covering (as shown in FIG. 5A).

Then, as in the first example, a terminal protection pattern 21 is formed to cover the entire surface of the interlayer connection film 22 and extend up to the second insulating film exposed surface 26 across the coverage boundary of the interlayer connection film 22 (as shown in FIG. 5B).

When a conductive liquid material is disposed in the opening, flown, and solidified to form the interlayer connection film 22 as described above, there are no discontinuous points which linearly cross, unlike in the exposed surface/edge portion intersection 25, on the surface of the interlayer connection film 22 (surface opposite to the side of the first metal film exposed surface). The surface of solidified interlayer connection film 22 assumes a shape of a gentle concave curve. Thus, void formation in the terminal protection pattern 21 can be prevented.

As a variation example of the second example, a same material as that for the interlayer connection film 22 disclosed in the second example having a film thickness of 700 nm may be disposed in a similar manner. With this arrangement, the interlayer connection film is shaped to be convex at the opening. However, there are no discontinuous points which linearly cross, unlike in the exposed surface/edge portion intersection 25. The surface of the interlayer connection film also assumes a shape of a gentle curve. Void formation in the terminal protection pattern 21 can be prevented.

### Third Example

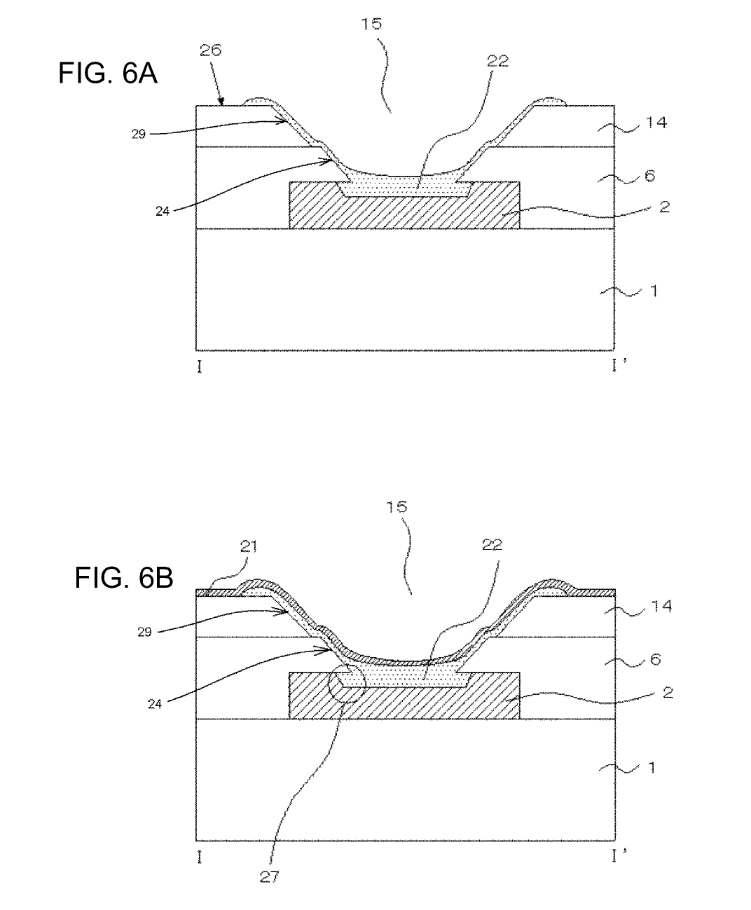

Next, a third example of the present invention will be described, using FIGS. 6A and 6B. A sectional view in each of FIGS. 6A and 6B is the view of a section in the vicinity of a gate terminal hole 15 as in the description of the first example.

A difference from the second example is that the surface of a first metal film 2 is etched to be recessed, and a lower surface end of a first insulating film edge portion 24 projects without being in contact with the first metal film 2.

In the fifth step (shown in FIG. 2) of opening the gate terminal hole 15, pixel connection hole 16, and data terminal hole 17, described in the first example, the second insulating film 14 and the first insulating film 6 are etched. When etching rate selectiveness between the first metal film 2 and the first insulating film 6 is inadequate at that time of etching, removal of the first metal film 2 takes place. Then, the lower surface end of the first insulating film 6 projects from the first metal film 2 and a space 27 is formed, as shown in FIG. 6B.

When a terminal protection pattern 21 is directly formed without forming an interlayer connection film 22 in this structure, a void is generated in the terminal protection pattern 21, as described above.

In this example, however, the interlayer connection layer 22 is formed by arranging a conductive liquid material is to fill the space 27 formed between the first metal film 2 and the first insulating film 6. Thus, a void is difficult to be generated in the terminal protection pattern 21.

In this example, the interlayer connection film 22 is formed, extending to a second insulating film exposed surface 26, and the terminal protection pattern 21 is disposed across the coverage boundary of the interlayer connection film 22, as in the second example (as shown in FIGS. 6A and 6B).

Assume, for example, that the film thickness of the interlayer connection film 22 is set to 60 nm in a structure where the first metal film 2 is etched to a depth on the order of 10 to 30 nm, and the lower surface end of the first insulating film 6 projects from the first metal film by approximately 0.05 μm. In case the thickness of the disposed interlayer connection film 22 is set to be larger than the etching thickness of the first metal film 2, the surface of the interlayer connection film 2 can be shaped like a more gentle curve than in a case the thickness of the interlayer connection film 22 is set to be smaller than the etching thickness of the first metal film 2. Thus, a void is difficult to be formed in the terminal protection pattern 21 disposed on an upper layer of the interlayer connection film 22.

In this example, the coverage region of the interlayer connection film 22 can also be set to the first insulating film edge portion 24 or a second insulating film edge portion, as in the first example.

Now, a description will be directed to a tendency toward formation of the structure in which the first metal film 2 is etched to be recessed, and the lower surface end of the first insulating film edge portion 24 projects without being in contact with the first metal film 2, with reference to a technical trend.

Removal of the insulating film on a mother substrate located at all openings must be simultaneously performed in a TFT substrate fabrication process.

Due to a trend toward an increase in the size of a screen in recent years, the size of a mother board has also become large. For this reason, an over-etching time during etching of the insulating film is prolonged. (the time taken for a first insulating film on the glass substrate at an opening to be etched and then for a first metal film to be exposed is referred to as a “just etching time”. In TFT manufacture, it is necessary that the time needed for etching the insulating film disposed on the glass at a plurality of openings be set to be longer than the just etching time. This prolonged time is the over-etching time. When etching rate selectivity between the first metal film 2 and the first insulating film 6 is not infinite, the first metal film 2 is etched.)

For that reason, due to the increased size of the mother board, there is the tendency that the first metal film 2 is etched to be more recessed, and the lower end portion of the first insulating film 6 projects from the first metal film 2.

Due to the reason as described above, the structure disclosed in the present example, in which the interlayer connection film 22 is disposed to fill the space 27 between the first metal film 2 and the first insulating film 6, becomes more effective.

### Fourth Example

Next, a fourth example of the present invention will be described.

The third example disclosed the case where the etching selectivity between the first metal film 2 and the first insulating film 6 was set to be low. This example discloses a case where the selectivity was set to be high, e.g. a case where the selectivity was set to be infinite. The description will be given, centering on a difference from the third example.

When the etching selectivity was set to be high, a lower surface end of a first insulating film 6 comes in contact with the surface of a first metal film 2, as shown in FIGS. 4A and 5A disclosed in the descriptions of the first and second examples. Thus, the space 27 as shown in FIG. 6B in the third example is not formed.

That is, this example includes a contact hole having a insulating film with an opening, disposed on a first metal film 2, an interlayer connection layer obtained by solidifying a conductive liquid material, and an upper metal film disposed on the interlayer connection layer so that the upper metal film extends across the coverage boundary region of the interlayer connection layer to come in contact with the insulating film. The interlayer connection layer is disposed, extending to cover at least the first metal film 2 exposed by the opening and an insulating film edge portion of the opening. The film thickness of the first metal film 2 exposed by the opening is thinner than the film thickness of the first metal film 2 which is not exposed by the opening.

In the gate terminal hole 15 in the first to third examples, after the first insulating film has been etched for removal, the conductive liquid material is disposed extending over the first metal film exposed surface 23 and the first insulating film edge portion 24, thereby forming the interlayer connection film 22. Then, the terminal protection pattern 21 is formed on an upper layer of the interlayer connection film 22 across the coverage region of the interlayer connection layer.

In a related art, after a first insulating film has been etched for removal, a terminal protection pattern 21 is formed on an upper layer of the first insulating film, without arranging an interlayer connection film 22.

When the related art and the art in each of the first to third examples are compared, these arts are similar only in a respect that the first insulating film is etched to form the opening, and then one or more kinds of films are formed, though the structures of the contact holes formed by these arts are completely different.

In a common TFT fabrication process, the first insulating film 6 is subject to dry etching for removal in terms of dimensional control. The angle of the edge portion of the first insulating film 6 is on the order of 50 to 80°. The angle of the edge portion of the second insulating film 14 is generally also in the range of 50 to 80°. More specifically, compared with the second insulating film 14, the first insulating film is often demanded to be a dense film in order to satisfy a requirement for TFT characteristics, and the angle of the edge portion of the first insulating film 6 is often larger than the angle of the edge portion of the second insulating film 14. That is, it often happens that the angle of the edge portion of the second insulating film 14 is approximately the same as or less than the angle of the edge portion of the first insulating film 6.

In case dry etching is used for the etching, a damaged layer including impurities caused by influences of plasma, an etching gas, a resist decomposed and then incorporated into a plasma gas and the like is apt to be formed, compared with wet etching.

Generally, the damaged layer has a high resistance. Thus, the damaged layer blocks electrical connection between the first metal film 2 and the interlayer connection film 22. In order to solve this problem, the damaged layer may be removed. When the first metal film 2 is set to an alloy film mainly composed of Al and subject to a chemical-solution treatment process using an acid or base, the damaged layer is removed and the metal film 2 is etched. Generally, the etching using a chemical solution has low directivity. Thus, the structure as described in the third example, tends to be formed where the first metal film 2 has a recessed shape and the lower surface end of the first insulating film edge portion 24 projects without being in contact with the first metal film 2.

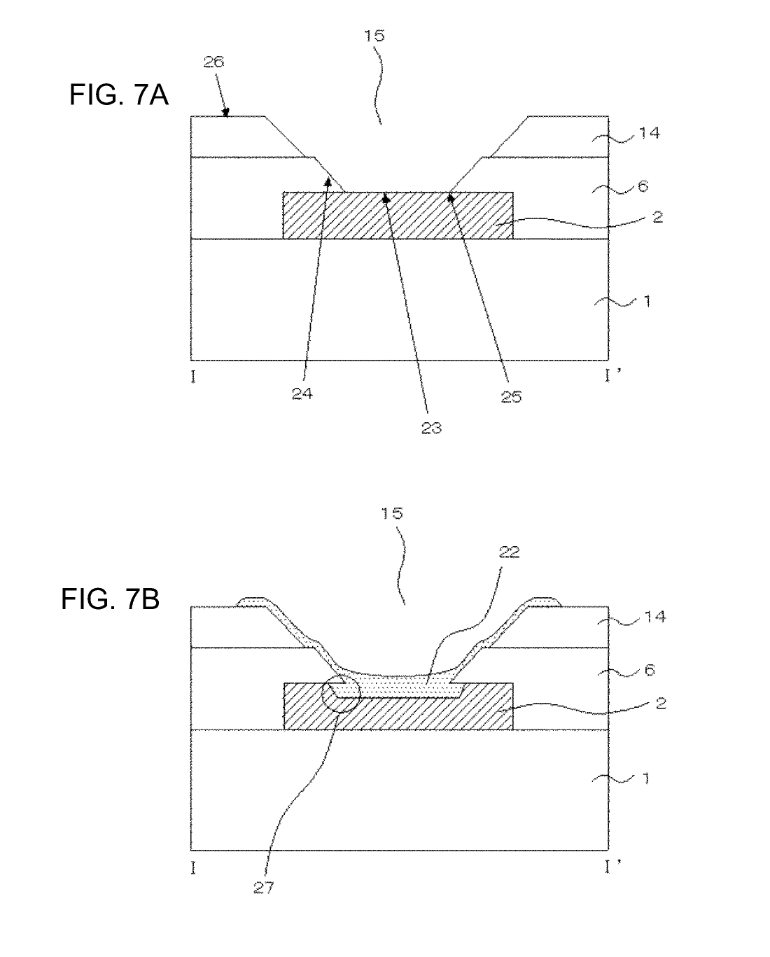

Then, the fourth example will be described in detail, using FIGS. 7A and 7B. A sectional view in each of FIGS. 7A and 7B is the view of a section in the vicinity of a gate terminal hole 15 as in the description of the first example.

A first insulating film 6 is subject to etching that has high selectivity with a first metal film 2, for removal, thereby forming the gate terminal hole 15. Herein, etching selectivity between the first insulating film 6 and the first metal film 2 is high. Thus, a first metal film exposed surface 23 and a first insulating film edge portion 24 discontinuously cross and get in contact with each other at an exposed surface/edge portion intersection 25 in such a manner that surface orientations of the films are varied (as shown in FIG. 7A).

Next, the first metal film 2 is cleaned so that slight etching of the first metal film 2 is performed. Herein, the first metal film 2 may be treated with a 0.6% TMAH solution to slightly remove the first metal film 2 by a depth on the order of 30 nm, which is a smaller value than the thickness of an interlayer connection film 22 that will be disposed later.

A structure in which the first metal film 2 is etched to be recessed and a lower surface end of the first insulating film edge portion 24 projects from the first metal film 2 is obtained by etching. Since the etching used herein is performed through the use of a chemical solution, the etching is isotropic, and an amount of the projection of the lower surface end of the first insulating film edge portion 24 is proportional to the amount of etching. This structure is similar to that in the third example.

Next, a conductive liquid material is disposed so that the conductive liquid material fills a space 27 formed by the first metal film 2 and the first insulating film 6 and the coverage boundary of the conductive liquid material extends up to a second insulating film exposed surface 26 across the gate terminal hole 15 (as shown in FIG. 7B).

Then, the conductive liquid material is solidified. With this arrangement, the surface of an interlayer connection film 22 assumes a shape of a gentle concave curve, where no discontinuous points which linearly cross are present, over an entire region of the first metal film exposed surface 23, first insulating film edge portion 24, a first insulating film exposed surface, a second insulating film edge portion, and second insulating film exposed surface 26. Herein, the thickness of the disposed interlayer connection film 22 may be thicker than the amount of the first metal film removed by the TMAH solution, and is set to 60 nm, for example. With this arrangement, no void is formed in a terminal protection pattern 21 on the interlayer connection film 22.

The process of slightly etching the first metal film 2 will be herein described in detail.

Since Al is an amphoteric metal, the Al can be etched and removed by an acid chemical solution or a base chemical solution. This holds true for an Al alloy mainly composed of Al, as well.

When both of the acid chemical solution and the base chemical solution are compared, it is preferable to use the base chemical solution. The reason for that is as follows. The resist described in the first to fourth examples is a resist soluble in base, and the damaged layer targeted for removal also includes a portion of the resist.

As described above, treatment by the base chemical solution can simultaneously achieve an effect of dissolving the damaged layer in addition to etching of the first metal film 2, which is efficient.

The acid or base chemical solution treatment may be a treatment in which the first metal film 2 is immersed in the chemical solution, or a treatment performed by showering the chemical solution. Further, in combination with the treatment, a mechanical treatment such as brushing or an ultrasonic treatment may be used to accelerate the effect. Further, when a surface active agent is mixed with the chemical solution to improve wettability of the first metal film, the process of removing the damaged layer can be more effectively carried out.

When the first metal film 2 is slightly etched as described above, the exposed surface of the first metal film 2 is cleaned, and a connection resistance value between the first metal film 22 and the interlayer connection film 22 can be reduced.

Each of the above descriptions in the first to fourth examples was directed to the structure and the fabrication method of the contact hole in which the interlayer connection film 22 obtained by solidifying the conductive liquid material is disposed between the lower layer metal film and the upper layer metal film, by illustrating the gate terminal hole 15. The first to fourth examples may be similarly applied to contact holes of the pixel connection hole 16, data terminal hole 17, and the like.

In this case, the first insulating film 6 is not disposed on the second metal film 9, and the second insulating film 14 is disposed over the second metal film 9.

In the pixel connection hole 16 or the data terminal hole 17, the conductive liquid material is disposed extending to a second insulating film edge portion across an exposed surface of the second metal film 9, an intersection (exposed surface/edge portion intersection) between the exposed surface of the second metal film and the second insulating film edge portion. Then, the conductive liquid material is solidified by losing fluidity, the surface of the interlayer connection film 22 assumes a shape of a gentle curve.

For that reason, a void is difficult to be formed in the terminal protection pattern 21 disposed on the interlayer connection film 22.

A coverage boundary where the interlayer connection film 22 is disposed may be the second insulating film edge portion as described above, or a second insulating film exposed surface 26.

In the structure and the fabrication method of the contact hole in which the interlayer connection film 22 is disposed in the gate terminal hole 15, pixel connection hole 16, data terminal hole 17, or the like, the coverage boundary of the interlayer connection film 22 may be set to be the same for all openings, or may be set to be the same or different among all the openings.

In the description of this example, the case where the thickness of the first insulating film 6 is set to 400 nm and the thickness of the second insulating film is set to 250 nm was disclosed. Assume that the metal film exposed surface areas of the gate terminal hole 15, pixel connection hole 16, and the data terminal hole 17 are set to be the same. Then, when the conductive liquid material for the interlayer connection film 22 that covers each of the openings just by the thickness of 500 nm is disposed, the second insulating film edge portion becomes the coverage boundary of the interlayer connection film 22 in the gate terminal hole 15, while the second insulating film exposed surface 26 becomes the coverage boundary of the interlayer connection film 22 in each of the pixel connection hole 16 and the data terminal hole 17.

When the amount of the disposed conductive liquid material is set to be constant irrespective of the kind of the opening as described above, a nozzle for inkjet or the like can be readily used for arranging the constant amount of the conductive liquid material as well as forming the conductive liquid material at a desired position. Thus, a high throughput can be obtained.

Further, it may be so disposed that the interlayer connection film 22 is formed only in the gate terminal hole 15 and the data terminal hole 17, and is not formed in the pixel connection hole 16, in view of interconnect corrosion (interconnect dissolution) after completion of the liquid crystal display device.

The reason for such an arrangement is as follows. The pixel connection hole 16 located within the panel in which liquid crystal has been sealed has a slower corrosion rate than the gate terminal hole 15 and data terminal hole 17 exposed to the outside world through the ACF having moisture permeability.

Further, the present invention may be applied to only a specific one of the gate terminal hole 15, pixel connection hole 16, and data terminal hole 17.

As described in the first example, the gate terminal hole 15, pixel connection hole 16, and data terminal hole 17 are simultaneously formed by etching the second interlayer insulating film 14 and the first interlayer insulating film 14.

Hence, after the second insulating film 14 has been removed and the second metal film 9 is exposed, the pixel connection hole 16 and the data terminal hole 17 are kept on being exposed to an etching environment until the first insulating film 6 of the gate terminal hole 15 is etched. For this reason, the second metal film 9 is easier to be etched than the first metal film 2.

As described in the third example, when an etching selection ratio between the second metal film 9 and the first insulating film 6 (which were the first metal film 2 and the first insulating film 6 in the description of the third example) is not adequate, a structure tends to be formed in which the second metal film 9 is etched to be recessed and a lower surface end of the first insulating film edge portion projects from the second metal film 9.

In this case, it is also effective to selectively dispose the interlayer connection film 22 in only openings of the second metal film 9 of the pixel connection hole 16, the data terminal hole 17, and the like.

It was described above that there was a trend toward an increase in the size of the mother board in manufacture of the liquid crystal display device. The current size of the mother substrate exceeds 2 m.

Currently, it has become a great technical challenge to ensure a constant etching rate within a surface of the mother board.

A difference among etching rates within the surface of the mother board is often fixed pattern that depends on characteristics of a manufacturing device, for example.

In a region of the first insulating film 6 or the second insulating film 14 etched by a fast etching rate, the metal film is etched to be recessed, and a lower surface end of the insulating film tends to project from the metal film.

For that reason, it is also effective to selectively dispose the interlayer connection film 22 just on a region where an amount of projection of the lower surface end of the insulating film from the metal film is large.

Next, the reason why tetradecane or decanol is used as the solvent of the conductive liquid material in the first to fourth examples is that this chemical has a property of dissolving the damaged layer to a certain degree and can be therefore incorporated into the interlayer connection film 22.

When the solvent of the conductive liquid material is made to have the function of dissolving the damaged layer, the damaged layer on the metal film exposed surface can be reduced. Connection resistance can be therefore more efficiently reduced.

The contact holes of the gate terminal hole 15, data terminal hole 17, pixel connection hole 16, and the like were illustrated in the first to fourth examples. The structure and the fabrication method of the contact hole of the present invention are not limited to those of the above-mentioned contact holes.

As an application example of the present invention, for example, the gate terminal hole 15 illustrated in each of the first to fourth examples connected to the gate interconnect on the TFT substrate and a terminal hole that has the same structure as the data terminal hole 17 illustrated in each of the first to fourth examples, not connected to the data interconnect are coupled by the film (upper metal film) that forms the pixel electrode. Then, the terminal hole that has the same structure as the data terminal hole 17 illustrated in each of the first to fourth examples, not connected to the data interconnect and TCP (Tape Carrier Package) bumps (terminals) are bonded by the ACF (Anisotropic Conductive Film) made of an organic resin, in which Au particles have been dispersed, thereby allowing manufacture of a liquid crystal panel.

Further, as an application example of a layer change added for description, where a protection TFT for preventing electro-static breakdown of a display pixel has been disposed aside from a TFT connected to the display pixel, a first contact hole which has the same structure as the pixel connection hole 16 illustrated in each of the first to fourth examples is disposed in a drain electrode, and a second contact hole for an interconnect for grounding or the like which is located on the same layer as a gate electrode and has the same structure as the gate terminal hole 15 illustrated in each of the first to fourth examples is disposed adjacent to the first contact hole, and both of the first and second contact holes are coupled by the film (upper layer metal film) that forms the pixel electrode.

As described above, the contact hole according to the present invention is not limited to the contact hole for the gate terminal hole 15, data terminal hole 17, pixel connection hole 16, or the like, and may be used as the contact hole for the layer change. The upper layer metal film can also be used as an interconnect rather than an electrode.

Next, the following samples were adjusted and tested in order to check the effect of the present invention. The structures of the samples that have been checked are contact holes that have the same structure as the gate terminal hole described in a corresponding one of the examples.

(First Experiment)

[Samples]
Sample 1: the sample described in the first example, where the interlayer connection film 22 has been formed up to the first insulating film edge portion.
Sample 2: the sample described in the first example, where the interlayer connection film 22 has been formed up to the second insulating film edge portion.
Sample 3: the sample described in the second example, where the interlayer connection film 22 has been formed extending to the second insulating film exposed surface 26.
Comparative sample: the sample of the related art described in [background art] where the interlayer connection film 22 is not disposed.

[Sample Conditions]
First metal film: the alloy film in [Non-patent Document 1] and [Non-patent Document 2] and an Al—Ni film containing 5% of Ni, each having a film thickness of 300 nm;
First insulating film: a SiNx film with a film thickness of 400 nm and an edge portion lower surface end angle of 75°;
Second insulating film: a SiNx film with a film thickness of 250 nm and an edge portion lower surface end angle of 50°;
Interlayer connection film (for samples 1 to 3): a film obtained by heating and solidifying the conductive liquid material in which Au nano-particles with a mean value of a particle diameter on the order of 5 nm have been dispersed into the solvent, and having a film thickness of 60 nm; and
Terminal protection pattern: an ITO film with a film thickness of 40 nm;

[Test Conditions]
(1) Each of the above-mentioned samples is connected to TCP bumps through the ACF to measure resistance (initial connection resistance); and
(2) Resistance of the sample, of which the initial resistance has been measured, is measured and a degree of corrosion progress of the gate terminal is checked (using microscopic observation) sequentially, under an environment at a high temperature (of 85° C.) and a high moisture of (60%), by applying DC 35V between a TCP wiring and the gate terminal.

[Test Results]

### Initial Resistance:

(large) comparative sample≈sample 1≈sample 2≧sample 3 (small);

### Resistance After High-Temperature and High-Moisture Test

(large) comparative sample>>sample 1≧sample 2≧sample 3 (small);

### Degree of Corrosion Progress After High-Temperature and High-Moisture Test

(large) comparative sample>>sample 1≧sample 2≧sample 3 (small);

(Second Experiment)

[Samples]
Sample 3: the sample described in the second example, where the interlayer connection film 22 has been formed extending to the second insulating film exposed surface 26.
Sample 4: the sample described in the fourth example, where the lower surface end of the first insulating film projects from the first metal film and the interlayer connection film 22 has been formed extending to the second insulating film exposed surface 26.
Comparative sample: the sample of the related art described in [background art] where the interlayer connection film 22 is not disposed.

[Sample Conditions]
First metal film (for gate terminal): the alloy film in [Non-patent Document 1] and [Non-patent Document 2]and an Al—Ni film containing 5% of Ni, each having a film thickness of 300 nm;
First insulating film: a SiNx film with a film thickness of 400 nm and an edge portion lower surface end angle of 75°;
Second insulating film: a SiNx film with a film thickness of 250 nm and an edge portion lower surface end angle of 50°;
Cleaning Agent Before Interlayer Insulating Film Formation;
Sample 3 and comparative sample: a non-ionic surface active agent;
Sample 4: the first metal film is etched to a depth of 30 nm by a 0.6%; TMAH solution to ensure a projection amount of the lower surface end of the first insulating film of 0.05 μm or less;
Interlayer connection film (for samples 3 and 4): a film obtained by heating and solidifying the conductive liquid material in which Au nanoparticles with an average particle diameter on the order of 5 nm have been dispersed into the solvent, and having a film thickness of 60 nm; and
Terminal protection pattern: ITO film with a film thickness of 40 nm

[Test Conditions]
(1) Each of the above-mentioned samples is connected to TCP bumps through the ACF to measure resistance (initial connection resistance); and
(2) Resistance of the sample, of which the initial resistance has been measured, is measured and a degree of corrosion progress of a gate terminal is checked (using microscopic observation) sequentially, under an environment at a high temperature (of 85° C.) and a high moisture of (60%), by applying DC 35V between a TCP interconnect and the gate terminal.

[Test Results]

### Initial Resistance:

(large) comparative sample≧sample 3>sample 4 (small)

### Resistance After High-Temperature and High-Moisture Test

(large) comparative sample>>sample 3>sample 4 (small)

### Degree of Corrosion Progress After High-Temperature and High-Moisture Test

(large) comparative sample>>sample 3≧sample 4>(small)

Effectiveness of the present invention can be concluded as follows, based on the experiment results described above.

The results of the first experiment will be described, and estimation will be made.

No initial resistance difference is not observed among the comparative sample, sample 1, and sample 2. This is estimated to be because the connection resistance value of the contact hole is mainly determined by the number of conductive particles mixed with the ACF which is present between a portion of the terminal protection pattern 21 and an opposing TCP bump portion. The portion of the terminal protection pattern 21 is located in a perpendicular direction of the first metal film exposed surface 23 at the gate terminal hole 15.

The reason why sample 3 showed an initial resistance value which is slightly smaller than those of the other samples is estimated to be as follows. The number of conductive particles which are present between the opposing TCP bump portion and the portion of the terminal protection pattern 21 located in the perpendicular direction of the first metal film exposed surface 23 at the gate terminal hole 15 is the same as those of the other samples. However, in sample 3, the interlayer connection film 22 is disposed extending to the second insulating film exposed surface 26. Thus, a void occurrence status in the terminal protection pattern 21 from a portion of the gate terminal hole 15 to the second insulating film exposed 26 is satisfactory. The region of the satisfactory void occurrence status is larger than those of the other samples. Accordingly, the conductive particles between the opposing TCP bump portion and a portion of the terminal protection pattern 21 located around the gate terminal hole 15 (second insulating film exposed surface 26) are involved in the reduction of the connection resistance value of sample 3 to a certain degree.

In order to reduce this initial resistance value, the size of the gate terminal hole may be increased or the number of the anisotropic conductive particles mixed with the ACF may be increase. With this arrangement, it is determined that a difference of the connection resistance value between the sample 3 and the other samples can be eliminated.

However, there is a trend toward a higher definition of liquid crystal devices in recent years. Thus, a bump pitch and a distance between terminal pitches tend to be reduced. Accordingly, it is not easy to increase the size of the gate terminal hole to get the area of the opening. Further, when a lot of the conductive particles are mixed with the ACF, a short circuit may occur between the bumps or terminals. Thus, this method does not match the technical trend. Accordingly, the structure of sample 4 may be a technique useful for reducing the initial connection resistance.

Next, the high-temperature and high-humidity test will be described. The comparative sample shows a connection resistance value after the test which is larger than those of samples 1 to 3. The large resistance value means that there is no terminal reliability.

The corrosion degree of the comparative sample was found to proceed more than those of samples 1 to 3. It was found that the corrosion proceeded in such a manner that the first metal film dissolves in the form of a frame along a region of the exposed surface/edge portion intersection 25 between the first metal film exposed surface 23 and the first insulating film edge portion 24.

The connection resistance values of samples 1 to 3 are expressed in the magnitude relationship of:

“sample 1≧sample 2>sample 3”,

which also matches the degrees of corrosion progress of samples 1 to 3 obtained by the microscopic observation.

This result means that the nearer a distance between a void formed in the terminal protection pattern and the exposed surface/edge portion intersection 25 between the first metal film exposed surface 23 and the first insulating film edge portion 24 is, the worse the corrosion degree is, and that terminal reliability is reduced by the progress of corrosion.

Corrosion in samples 1 to 3 was confirmed at the position of a region of the exposed surface/edge portion intersection 25 between the first metal film exposed surface 23 and the first insulating film edge portion 24, as in the comparative example. However, the degree of the corrosion in samples 1 to 3 is far better than the comparative sample, and the corrosion is quite localized in the shape of a sesame seed.

The progression of the corrosion is estimated as follows. Moisture including vapor first passes through the bulk of the organic resin of the ACF or an interface between the organic resin and the terminal protection pattern and reaches a void in the terminal protection pattern 21 (the coverage boundary of the terminal protection pattern in sample 3).

Next, in samples 1 to 3, the moisture that has reached the void passes through the terminal protection pattern 21, reaches the surface of the insulation film, then passes through an interface between the terminal protection pattern 21 and the insulating film, and then reaches the coverage boundary of the interlayer connection film.

In the comparative sample, the moisture that has reached the void reaches the exposed surface/edge portion intersection 25 between the first metal film exposed surface 23 and the first insulating film edge portion 24 at a time of passing through the terminal protection pattern 21. Then, the moisture corrodes the first metal film.

In samples 1 to 3, it is concluded that only after the moisture has passed through an interface between the interlayer connection film and the insulating film 6, the moisture reaches the exposed surface/edge portion intersection 25 between the first metal film exposed surface 23 and the first insulating film edge portion 24 and effects to corrode the first metal film.

With the above-mentioned models, the result of the experiment in which samples 1 to 3 have higher terminal reliability than the comparative example is understood.

Further, the corrosion in samples 1 to 3 is not uniform in the form of the frame, unlike in the comparative sample, and is localized in the shape of the sesame seed. Thus, it is estimated that the moisture has passed through a certain weak spot of the interface between the interlayer connection film 22 and the insulating film, and a portion of the first metal film corresponding to the spot through which the moisture has passed has been probably corroded preferentially.

Next, a description will be directed to reasons why the terminal protection pattern 21 is disposed across the coverage boundary of the interlayer connection film 22.

A first reason is as follows. It is estimated that moisture first enters through a void in the terminal protection pattern 21 (a boundary portion between the terminal protection pattern and the second insulating film when there is no void as in sample 3), and then reaches the interface between the terminal protection pattern and the insulating film through the path described above. Then, as in passage of moisture through the interface between the interlayer connection film 22 and the insulating film, it is estimated that the moisture reaches the coverage boundary region of the interlayer connection film 22 through a certain weak spot of the interface between the terminal protection pattern 21 and the insulating film as well. It is estimated next that the moisture reaches the first metal film through the weak spot between the interlayer connection film 22 and the insulating film, thereby allowing corrosion of the metal film to occur.

Now, assume that the terminal protection pattern 21 is disposed not to extend across the coverage boundary of the interlayer connection film 22. Then, moisture passes only through the interface between the interlayer connection film 22 and the insulating film, thereby allowing corrosion to occur.

For that reason, when the terminal protection pattern 21 is disposed across the coverage boundary of the interlayer connection film 22, a probability that the moisture reaches to the exposed surface/edge portion intersection 25 between the first metal film exposed surface 23 and the first insulating film edge portion 24 can be estimated to be the product of weak-spot probabilities of respective boundary surfaces. Thus, the probability that the moisture passes through the exposed surface/edge portion intersection 25 can be remarkably reduced. Further, the time taken for the moisture to reach the exposed surface/edge portion intersection 25 can also be delayed.

The present invention has the structure in which the terminal protection pattern 21 is disposed, extending across the coverage boundary of the interlayer connection film 22. When the terminal protection pattern 21 is disposed not to extend across the coverage boundary of the interlayer connection film 22, both of the terminal protection pattern 21 and the interlayer connection film 22 come into contact with the ACF. For that reason, a local battery is produced between both of the metals due to the moisture. Thus, this structure may not be advantageous for preventing corrosion. This problem is already described in “SUMMARY”.

A second reason is that corrosion resistance of the transparent conductive film of ITO, IZO, SnO, or the like, which is the upper metal film, is high. When the corrosion resistance is high, use of the metal for the pixel electrode for the terminal protection pattern 21 as well may be easy for those skilled in the art. There is another reason for this use.

The another reason is as follows. When the upper layer metal film covers the interlayer connection film 22 and is extended to the external insulating film, permeation of moisture that may reach the interlayer connection film 22 can be prevented. As a result, the interlayer connection film 22 located under the upper metal film can be made of a material that is inferior in corrosion resistance.

Use of an Ag-based material for the lower-layer metal of the contact hole in the terminal portion without being covered by the terminal protection pattern, for example, (which indicates a contact hole in a related art where first and second metal films are made of Ag and a terminal protection pattern is directly disposed over the first and second metal films, for example) is not regarded as being appropriate in terms of reliability. When the terminal protection pattern 21 is formed, extending to cover the entire surface of the interlayer connection film 22 and outside the entire surface of the interlayer connection film 22 as in the present invention, terminal reliability can be ensured even if the Ag-based material is used for the lower layer metal film.

When the corrosion-resistant upper layer metal film covers the interlayer connection film 22 and the corrosion-resistant upper layer metal film is extended outside the interlayer connection film 22 in this manner, the permeation of moisture can be prevented. When a material for the interlayer connection film 22 is selected, it is more effective to select the material so that a contact potential between each of the upper layer metal film/interlayer connection film and the interlayer connection film/lower layer metal film is reduced, rather than in terms of a corrosion difficulty level of the interlayer connection film 22 itself.

A third reason is as follows. The present invention disclosed the case where the terminal protection pattern 21 was formed by the sputtering method. Use of this method is related to suppression of a corrosion level and ensuring of terminal resistance by arranging the upper metal film on the insulating film across the interlayer connection film 22.

When the sputtering method is used, sputtered particles physically collide with the insulating films and are bombarded into the insulating film. As a result, the insulating film can be damaged.

For that reason, a mixed layer composed of a mixture of components of both of the insulating film and the terminal protection pattern can be generated at the interface between the insulating film and the terminal protection pattern. With this arrangement, it is possible to prevent the moisture from permeating into an interface between the terminal protection pattern and the insulating film.

As the insulating film which prevents the permeation of moisture, an organic film made of a novolac resin, an acryl resin, or a styrene resin is preferable, compared with an inorganic film such as the SiNx film or SiOx film. The reason for the preference is that the organic film has a lower hardness than the inorganic film such as the SiNx film, and a more reliable mixed layer thus can be formed.

Next, results of the second experiment will be described.

The relationship between the test results of the comparative sample and sample 3 was already described in the description of the first experiment. Herein, the results of samples 3 and 4 will be described.

A difference between samples 3 and 4 is that the interlayer connection film 22 is disposed after the metal film surface has been etched or the interlayer connection film 22 is disposed without etching the metal film surface. The metal film surface is not etched in sample 3, while the metal film surface has been etched in sample 4.

It was not determined that a difference in resistance values was not increased before and after the high-temperature, high-moisture test (before the high-temperature, high-moisture test: initial resistance) in samples 4 and 3. Compared with sample 3, sample 4 showed low resistance values of a substantially same level as in sample 3 before and after the high-temperature and high-moisture test. It is determined that the low resistance values of sample 4 are caused by removal of the damaged layer by etching of the first metal film 2.

Removal of the damaged layer by etching is readily confirmed by measuring amounts of carbon (hereinafter referred to as C) and fluorine (hereinafter referred to as F) of the surface of the first metal film by SIMS (secondary ion mass spectrometry). F is estimated to be derived from an etching gas for the first insulating film.

Sample 3 shows a slightly unfavorable progression degree of corrosion after the high-temperature and high-moisture test observed by the microscope (though the difference between the resistance values measured before and after the high-temperature and high-moisture test was in such a level that could not be determined to be increased, as described above). This is estimated to be caused by one or both of the following reasons. One reason is that both of moisture and F included in the damaged layer are involved in promoting corrosion of the metal film. The other reason is that, since sample 4 is of the structure where the lower surface end of the first insulating film edge portion projects from the first metal film, a path through which moisture reaches the metal film is long.

Herein, the contact hole of the gate terminal hole 15 is described as the typical example. Even when the data terminal hole 17 is employed, it is estimated that the similar result is obtained, excepting that the first insulating film is not disposed.

Next, the pixel connection hole 16 will be described.

The pixel connection hole 16 located within the panel in which liquid crystal is sealed has a slower corrosion rate than the gate terminal hole 15 and the data terminal 17 described above.

The reason for the slower corrosion rate is estimated as follows. Since the former is located within the panel in which the liquid crystal is sealed, the former has a small degree of the permeation of moisture unlike the latter which is exposed to the outside world and/or may scarcely come into contact with various corrosion gases mixed in the air.

On the pixel electrode 20 located on the top surface of the pixel electrode hole, the ACF is not disposed, and the liquid crystal material is located, unlike the gate terminal hole 15 and the data terminal hole 17.

It is important to reduce a connection resistance value between a region of the pixel electrode 20 that contributes to display and the drain electrode 12 in the pixel connection hole 16. The region of the pixel electrode that contributes to display is a peripheral section in which the pixel electrode 20 located on the top surface of the pixel connection hole 16 extends.

When a void is generated in an intersection between the exposed surface of the drain electrode 12 formed of the second metal film 9 and a lower surface end of the second insulating film edge portion in the pixel electrode 20, the contact resistance value between the region of the pixel electrode 20 that contributes to display (peripheral region of the pixel connection hole 16) and the drain electrode 12 increases.

In the related art structure where the interlayer connection film 22 is not disposed, voids occur in such a manner that the voids are framed along the lower surface end and an upper surface end of the second insulating film edge portion. Thus, a contact resistance value between the region of the pixel electrode that contributes to display and the drain electrode 12 increases.

However, when the interlayer connection film 22 is formed between the second metal film 9 and the pixel electrode 20 as in this example, a void generated in the pixel electrode 20 can be prevented, and a contact resistance value between the region of the pixel electrode that contributes to display and the drain electrode 12 can be reduced.

When the coverage boundary region of the interlayer connection film 22 is extended to the second insulating film edge portion, a void is generated only at the upper surface end of the second insulating film. Thus, a contact resistance value between the region of the pixel electrode that contributes to display and the drain electrode 12 can be reduced.

Further, when the coverage boundary region of the interlayer connection film 22 is extended up to the second insulating film exposed surface 26, occurrence of the void at the upper surface end of the second insulating film can also be prevented. Thus, the contact resistance value between the region of the pixel electrode that contributes to display and the drain electrode 12 can be further made preferable.

Further, when the surface of the second metal film is slightly etched and then cleaned, the damaged layer can be removed, as described above. Thus, a more preferable pixel connection hole can be obtained.

As described above, according to the present invention, a contact hole structure having a low initial connection resistance value, which is highly corrosion resistant and is reliable, and a method of manufacturing the contact hole can be provided.

In the description of the present invention, the alloy mainly composed of Al that is highly corrosive, for which the present invention becomes particularly effective, was illustrated and described. A metal that is corrosion resistant may also be adopted for the present invention, and is not excluded.

When the present invention is applied to the structure described in the “background art”, in which the cover film is disposed on the first metal film or the second metal film, a void in the contact hole can be eliminated. When the interlayer connection film is disposed after the first metal film or the second metal film has been slightly etched to remove the damaged layer, a connection resistance value can also be reduced.

In a liquid crystal device in a current state, Cr, Mo, Ti, or an alloy of Cr, Mo, and Ti may be employed as the cover film. However, when use of the display device employing these metals is kept on, the corrosion of a terminal gradually proceeds even if the corrosion speed of the terminal is lower than that of the film of the alloy mainly composed of Al.

It is additionally described that the problem of terminal corrosion is more manifest in a liquid crystal device for industrial use which is often used in an atmosphere of a corrosive gas of S (sulfur) or Cl (chlorine), for example.

In the examples, the liquid crystal display device in particular was illustrated and described. The present invention can also be preferably carried out for a PDP (Plasma Display Panel) display device and an organic EL (organic electroluminescence) display device in which a similar contact hole is present.

Operations and effects of the above-mentioned examples are as follows.

By arranging the interlayer connection layer formed by solidifying the conductive liquid material to extend over at least the insulating film opening and the insulating film edge portion, and further by arranging the upper metal film so that the upper metal film is extended to cover the entirety of the interlayer connection layer and the insulating film which is adjacent to the interlayer connection layer across the interlayer connection layer, a contact hole with a low connection resistance and a high corrosion resistance can be provided.

By setting the step at which the maximum temperature is attained to a step before the conductive liquid material is disposed in the fabrication process of the display device, a material for the lower layer metal film mainly composed of Al can be suitably used.

When the pressure reduction method is employed for solidifying the conductive liquid material, reduction of a heating period of time and lowering of temperature can be achieved. Thus, oxidation of the conductive liquid material can be prevented, and a contact hole with a low connection resistance can be provided.

The damaged layer on the surface of the lower layer metal film is made to dissolve by the conductive liquid material so that the damaged layer is made to be diffused and hence an amount of a corrosion element per volume on the surface of the lower surface metal film can be reduced. A contact hole with a low connection resistance and a high corrosion resistance can be provided.

By etching a portion of the lower layer metal film together with the damage layer on the surface of the lower layer metal film before the conductive liquid material is disposed, the contact hole with a low connection resistance and a high corrosion resistance can be provided.

When the upper layer metal film is formed on the surface of the insulating film by sputtering, the mixed layer of the upper layer metal film and the insulating film can be formed at the interface between the upper layer metal film and the insulating film. Thus, the structure of a contact hole with a high corrosion resistance can be provided. Further, when the insulating film is set to an organic film, a higher corrosion resistance can be achieved.

### INDUSTRIAL APPLICABILITY

Accordingly, the present invention can be applied to display devices in general such as liquid crystal display devices, PDP display devices, and organic EL display devices.

Modification and adjustment of the exemplary embodiment and the examples are possible within the scope of the overall disclosure (including claims) of the present invention, and based on the basic technical concept of the invention. Various combinations and selections of various disclosed elements are possible within the scope of the claims of the present invention. That is, the present invention of course includes various variations and modifications that could be made by those skilled in the art according to the overall disclosure including the claims and the technical concept.

1. A display device comprising a contact hole including:
a lower layer metal film disposed on a substrate;
an insulating film disposed on the lower layer metal film, insulating film having an opening;
an interlayer connection layer formed by solidifying a conductive liquid material disposed extending to cover at least the lower layer metal film exposed by the opening and an edge portion of the opening of the insulating film; and
an upper layer metal film disposed on the interlayer connection layer, the upper layer metal film being extended across a coverage boundary region of the interlayer connection layer to come in contact with the insulating film;
a film thickness of the lower layer metal film exposed by the opening being thinner than a film thickness of a part of the lower layer metal film not exposed by the opening.

2. The display device according to claim 1, wherein the interlayer connection layer is extended across the edge portion of the opening of the insulating film to an exposed surface of the insulating film.

3. The display device according to claim 1, wherein a film thickness of the interlayer connection layer is thicker than a difference between the film thickness of the lower layer metal film exposed by the opening and the film thickness of the lower layer metal film not exposed by the opening.

4. The display device according to claim 1, wherein the lower layer metal film includes at least a contact hole of a gate terminal hole section electrically connected to a gate interconnect or a contact hole of a data terminal hole section electrically connected to a data interconnect.

5. The display device according to claim 1, wherein the lower layer metal film exposed by the opening comprises a contact hole of a pixel connection hole section electrically connected to at least a drain electrode.

6. The display device according to claim 1, wherein a metal film located on a top surface of the lower layer metal film includes an alloy film including Al as a main component.

7. The display device according to claim 1, wherein the upper layer metal film includes any material selected from the group consisting of ITO, IZO, and SnO.

8. The display device according to claim 1, wherein an insulating film located on a top surface of the insulating film includes an organic film.

9. The display device according to claim 8, wherein the organic insulating film located on the top surface includes a resin selected from the group consisting of novolac resin, an acryl resin, and a styrene resin.

10. The display device according to claim 1, wherein the interlayer connection layer formed by solidifying the conductive liquid material includes at least one of Au, Ag, Cu, Ni, Pt, Pd, and ITO.

11. The display device according to claim 1, wherein the display device includes a liquid crystal display device.

12. A display device including a connection structure, the connection structure comprising:
an interlayer connection film formed by arranging a conductive liquid material at an opening in an insulating film and then solidifying the conductive liquid material,
the insulating film covering a first metal film which is disposed on a substrate or on an upper layer of the substrate,
the opening exposing a surface of the first metal film and then solidifying the conductive liquid material,
the interlayer connection film covering a bottom of the opening and covering the opening wall to at least a part of the height of the opening wall,
the interlayer connection film having a surface shape at the opening set to a concave or convex curved surface; and
a second metal layer formed on the interlayer connection film to cover at least a coverage region of the interlayer connection film, the second metal layer having a surface shape at the opening being set to a concave or convex curved surface corresponding to the interlayer connection film.

13. The display device according to claim 12, wherein the first metal film has a recess section having a predetermined depth formed in a region exposed by the opening,
the recess section of the first metal film being filled with the interlayer connection film,
a film thickness of the interlayer connection film being thicker than the depth of the recess section of the first metal film.

14. The display device according to claim 13, wherein at the opening, a lower surface end of an edge portion of the insulating film that constitutes the opening wall is protruded from an upper end of the recess section of the first metal film to an inside of the opening,
a space surrounded by the recess section of the first metal film and a protruded section of the lower surface end of the insulating film edge portion being filled with the interlayer connection film.

15. The display device according to claim 12, wherein the film thickness of the interlayer connection film gets thinner toward a boundary of the coverage region at the opening wall covered by the interlayer connection film.

16. The display device according to claim 12, wherein the insulating film includes a plurality of laminated insulating films, and the interlayer connection film covers the opening wall of at least one of the laminated insulating films at a lowest layer.

17. The display device according to claim 2, wherein a film thickness of the interlayer connection layer is thicker than a difference between the film thickness of the lower layer metal film exposed by the opening and the film thickness of the lower layer metal film not exposed by the opening.

18. The display device according to claim 2, wherein the lower layer metal film includes at least a contact hole of a gate terminal hole section electrically connected to a gate interconnect or a contact hole of a data terminal hole section electrically connected to a data interconnect.

19. The display device according to claim 3, wherein the lower layer metal film includes at least a contact hole of a gate terminal hole section electrically connected to a gate interconnect or a contact hole of a data terminal hole section electrically connected to a data interconnect.

20. The display device according to claim 2, wherein a metal film located on a top surface of the lower layer metal film includes an alloy film including Al as a main component.
